(19) United States
(12) Patent Application Publication
(10) Pub. No.: US 2025/0210112 A1
(43) Pub. Date: Jun. 26, 2025

(54) SEMICONDUCTOR MEMORY DEVICE

(71) Applicant: Kioxia Corporation, Tokyo (JP)

(72) Inventor: Koji HOSONO, Fujisawa Kanagawa (JP)

(73) Assignee: Kioxia Corporation, Tokyo (JP)

(21) Appl. No.: 19/074,253

(22) Filed: Mar. 7, 2025

Related U.S. Application Data
(63) Continuation of application No. PCT/JP2022/045360, filed on Dec. 8, 2022.

(51) Int. Cl. G11C 16/10; G11C 16/04; G11C 16/08; G11C 16/34

(52) U.S. Cl. CPC G11C 16/102; G11C 16/0483; G11C 16/08; G11C 16/3459

(57) ABSTRACT

According to an embodiment, a semiconductor memory device includes a first chip which includes first and second memory cells, a second chip which includes third and fourth memory cells, and a third chip which includes a row decoder. In a first program operation of the first memory cell, the row decoder applies a first program voltage to the first word line. In a first program operation of the second memory cell, the row decoder applies a second program voltage higher than the first program voltage to the first word line. In a first program operation of the third memory cell, the row decoder applies a third program voltage to the first word line. In a first program operation of the fourth memory cell, the row decoder applies a fourth program voltage higher than the third program voltage to the first word line.

### CROSS-REFERENCE TO RELATED APPLICATIONS

This application is a Continuation application of PCT Application No. PCT/JP2022/045360, filed Dec. 8, 2022, the entire contents of all of which are incorporated herein by reference.

### FIELD

Embodiments described herein relate generally to a semiconductor memory device.

### BACKGROUND

As a semiconductor memory device, a NAND flash memory is known.

### BRIEF DESCRIPTION OF THE DRAWINGS

FIG. 1 is a block diagram illustrating an overall configuration of a memory system including a semiconductor memory device according to a first embodiment.

FIG. 2 is a plan view illustrating a circuit configuration of a memory cell array included in the semiconductor memory device according to the first embodiment.

FIG. 3 is a perspective view illustrating the circuit configuration of the memory cell array included in the semiconductor memory device according to the first embodiment.

FIG. 4 is a circuit diagram of a row decoder included in the semiconductor memory device according to the first embodiment.

FIG. 5 is a cross-sectional view illustrating an arrangement of array chips and a circuit chip included in the semiconductor memory device according to the first embodiment.

FIG. 6 is a perspective view illustrating the arrangement of the array chips and the circuit chip included in the semiconductor memory device according to the first embodiment.

FIG. 7 is a cross-sectional view of the memory cell array included in the semiconductor memory device according to the first embodiment.

FIG. 8 is a cross-sectional view of the memory pillar taken along lines I-I and II-II in FIG. 7.

FIG. 9 is a diagram illustrating a threshold voltage distribution and data allocation of a triple level cell (TLC) in the semiconductor memory device according to the first embodiment.

FIG. 10 is a diagram illustrating a relationship between a first program mode and a second program mode in a write operation in the semiconductor memory device according to the first embodiment.

FIG. 11 is a graph illustrating a relationship between a threshold voltage and a program voltage of a memory cell transistor in the semiconductor memory device according to the first embodiment.

FIG. 12 is a timing chart illustrating a voltage of each interconnect in the write operation in the semiconductor memory device according to the first embodiment.

FIG. 13 is a command sequence of the write operation in the semiconductor memory device according to the first embodiment.

FIG. 14 is a configuration diagram of a memory address in the semiconductor memory device according to the first embodiment.

FIG. 15 is a diagram illustrating a writing order of data based on the memory address shown in FIG. 14.

FIG. 16 is a view illustrating an example of selection of an operation mode in the memory cell array included in the semiconductor memory device according to the first embodiment.

FIG. 17 is a flowchart of the write operation in the semiconductor memory device according to the first embodiment.

FIG. 18 is a plan view illustrating a circuit configuration of a memory cell array included in the semiconductor memory device according to a first modification of the first embodiment.

FIG. 19 is a perspective view illustrating the circuit configuration of the memory cell array included in the semiconductor memory device according to the first modification of the first embodiment.

FIG. 20 is a view illustrating an example of selection of an operation mode in the memory cell array included in the semiconductor memory device according to the first modification of the first embodiment.

FIG. 21 is a cross-sectional view illustrating an arrangement of array chips and a circuit chip included in a semiconductor memory device according to a second modification of the first embodiment.

FIG. 22 is a perspective view illustrating a circuit configuration of a memory cell array included in a semiconductor memory device according to the second modification of the first embodiment.

FIG. 23 is a view illustrating an example of selection of an operation mode in the memory cell array included in the semiconductor memory device according to the second modification of the first embodiment.

FIG. 24 is a view illustrating an example of selection of an operation mode in a memory cell array included in a semiconductor memory device according to a second embodiment.

FIG. 25 is a view illustrating an example of selection of the operation mode in the memory cell array included in the semiconductor memory device according to the second embodiment.

FIG. 26 is a flowchart of the write operation in the semiconductor memory device according to the second embodiment.

FIG. 27 is a view illustrating an example of selection of an operation mode in the memory cell array included in the semiconductor memory device according to a modification of the second embodiment.

FIG. 28 is a view illustrating an example of selection of the operation mode in the memory cell array included in the semiconductor memory device according to the modification of the second embodiment.

FIG. 29 is a view illustrating an example of selection of an operation mode in a memory cell array included in a semiconductor memory device according to a third embodiment.

FIG. 30 is a flowchart of the write operation in the semiconductor memory device according to the third embodiment.

### DETAILED DESCRIPTION

In general, according to one embodiment, a semiconductor memory device includes a first chip, a second chip, and a third chip. The first chip includes a first pillar including a first memory cell and a second pillar including a second memory cell. The second chip includes a third pillar including a third memory cell and a fourth pillar including a fourth memory cell. The third chip includes a row decoder to which a first word line coupled to a gate of each of the first to the fourth memory cells is coupled and a controller configured to execute a write operation in which a program loop is repeated. The program loop includes a program operation and a program verify operation. In a first time of the program operation of the write operation of the first memory cell, the row decoder applies a first program voltage to the first word line. In a first time of the program operation of the write operation of the second memory cell, the row decoder applies a second program voltage higher than the first program voltage to the first word line. In a first time of the program operation of the write operation of the third memory cell, the row decoder applies a third program voltage to the first word line. In a first time of the program operation of the write operation of the fourth memory cell, the row decoder applies a fourth program voltage higher than the third program voltage to the first word line.

Hereinafter, embodiments will be described with reference to the drawings. In the following description, components having substantially the same functions and configurations are denoted by the same reference numerals. Redundant description may be omitted if unnecessary. In addition, each of the embodiments described below illustrates an apparatus and a method for embodying the technical idea of the embodiment. The technical idea of the embodiment does not specify the material, shape, structure, arrangement, and the like of the components as described below. Various modifications can be made to the technical idea of the embodiment without departing from the gist of the invention. These embodiments and modifications of the embodiments are included in the scope of the invention described in the claims and the equivalent thereof.

### 1. First Embodiment

A semiconductor memory device according to a first embodiment will be described.

### 1.1 Configuration

### 1.1.1 Overall Configuration of Semiconductor Memory device

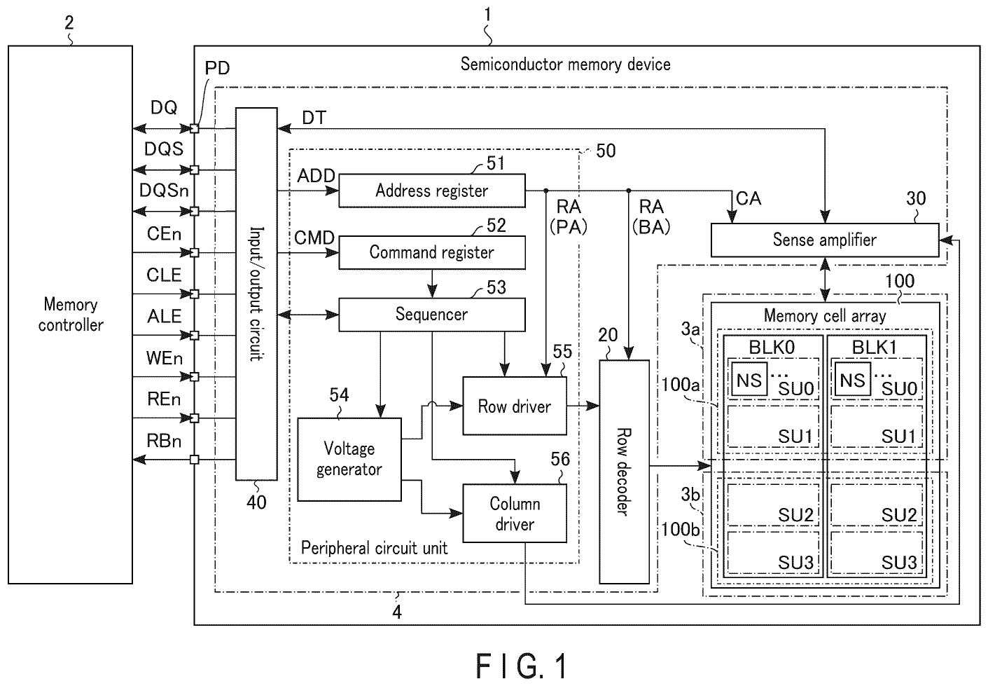

First, an example of an overall configuration of a semiconductor memory device 1 will be described with reference to FIG. 1. FIG. 1 is a block diagram illustrating an overall configuration of a memory system including the semiconductor memory device 1. In the example of FIG. 1, a part of coupling between the components is indicated by arrow lines, but the coupling between the components is not limited thereto.

As illustrated in FIG. 1, the memory system includes the semiconductor memory device 1 and a memory controller 2.

The semiconductor memory device 1 is, for example, a three-dimensional stacked NAND flash memory. The three-dimensional stacked NAND flash memory includes a plurality of non-volatile memory cell transistors arranged three-dimensionally on a semiconductor substrate.

The memory controller 2 instructs the semiconductor memory device 1 to perform a read operation, a write operation, an erase operation, and the like based on a request from a host device (not illustrated). In addition, the memory controller 2 manages a memory space of the semiconductor memory device 1.

The semiconductor memory device 1 includes a plurality of external coupling terminals PD. The semiconductor memory device 1 is coupled to the memory controller 2 via the external coupling terminals PD. In addition, the semiconductor memory device 1 is supplied with a power supply voltage from the outside via the external coupling terminals PD.

The semiconductor memory device 1 is configured to be controllable by the memory controller 2. For example, the semiconductor memory device 1 transmits and receives a signal DQ and timing signals DQS and DQSn to and from the memory controller 2. The signal DQ is, for example, data DT, a memory address ADD, or a command CMD. The memory address ADD is information indicating a location of a memory cell transistor in a memory cell array 100. For example, the command CMD includes instructions for executing a read operation, a write operation, an erase operation, and the like. The timing signals DQS and DQSn are timing signals used at the time of input and output of the data DT. The timing signal DQSn is an inverted signal of the timing signal DQS.

In addition, the semiconductor memory device 1 receives various control signals from the memory controller 2. The control signals include, for example, a chip enable signal CEn, a command latch enable signal CLE, an address latch enable signal ALE, a write enable signal WEn, and a read enable signal REn.

The chip enable signal CEn is a signal for enabling the semiconductor memory device 1. The command latch enable signal CLE is a signal indicating that the signal DQ is a command. The address latch enable signal ALE is a signal indicating that the signal DQ is an address. The write enable signal WEn is a signal for fetching the signal DQ if the signal DQ is the command CMD or the memory address ADD. Every time the signal WEn is toggled, the command CMD or the memory address ADD is fetched into the semiconductor memory device 1. The read enable signal REn is a signal for the memory controller 2 to read data from the semiconductor memory device 1. For example, at the time of data output, the semiconductor memory device 1 generates the signals DQS and DQSn based on the signal REn.

The semiconductor memory device 1 transmits a ready/busy signal RBn to the memory controller 2. The ready/busy signal RBn is a signal indicating whether the semiconductor memory device 1 is in a state in which the semiconductor memory device 1 is not able to receive the command CMD from the memory controller 2 (busy state) or in a state in which the semiconductor memory device 1 is able to receive the command CMD from the memory controller 2 (ready state).

Next, an internal configuration of the semiconductor memory device 1 will be described.

The semiconductor memory device 1 includes a plurality of array chips 3 and a circuit chip 4. In the example illustrated in FIG. 1, the semiconductor memory device 1 includes two array chips 3a and 3b. Note that the number of the array chips 3 is not limited to two.

Each of the array chips 3 is a chip provided with an array of non-volatile memory cell transistors.

The circuit chip 4 is a chip provided with a circuit for controlling the array chips 3. For example, the semiconductor memory device 1 has a structure in which the plurality of array chips 3 and the circuit chip 4 are bonded together (hereinafter, also referred to as a “bonded structure”). Hereinafter, the array chips 3 and the circuit chip 4 are simply referred to as a “chip” in a case where a type of the chip is not limited.

The semiconductor memory device 1 includes the memory cell array 100. The memory cell array 100 is a region in which non-volatile memory cell transistors are three-dimensionally arranged. The memory cell array 100 is provided in the array chips 3a and 3b. Hereinafter, a part of the memory cell array 100 provided in the array chip 3a will be referred to as a “memory cell array 100a”. A part of the memory cell array 100 provided in the array chip 3b is referred to as a “memory cell array 100b”. That is, the memory cell array 100 includes the memory cell arrays 100a and 100b.

The memory cell array 100 includes a plurality of blocks BLK. In the example of FIG. 1, the memory cell array 100 includes two blocks BLK0 and BLK1. Each of the blocks BLK is, for example, a set of a plurality of memory cell transistors from which data is collectively erased. In the present embodiment, one block BLK is provided in a region where a part of the memory cell array 100a and a part of the memory cell array 100b are combined. That is, each of the block BLK includes a plurality of memory cell transistors provided in the memory cell array 100a and a plurality of memory cell transistors provided in the memory cell array 100b. The plurality of memory cell transistors in the blocks BLK are associated with a row and a column.

The blocks BLK include a plurality of string units SU. The string units SU constitute, for example, a set of a plurality of NAND strings NS collectively selected during the write operation or the read operation. In the example of FIG. 1, each of the blocks BLK includes four string units SU0, SU1, SU2, and SU3. For example, the memory cell array 100a (array chip 3a) includes the string units SU0 and SU1 of each of the blocks BLK. The memory cell array 100b (array chip 3b) includes the string unit SU2 and the string unit SU3 of each of the blocks. Note that an arrangement of the string units SU included in the array chips 3a and 3b is arbitrary.

Each of the string units SU includes a plurality of NAND strings NS. Each of the NAND strings NS includes a set of a plurality of memory cell transistors coupled in series.

Note that the number of blocks BLK in the memory cell array 100 and the number of string units SU in the block BLK are arbitrary. A circuit configuration of the memory cell array 100 will be described later.

Next, the circuit chip 4 will be described. The circuit chip 4 includes a row decoder 20, a sense amplifier 30, an input/output circuit 40, and a peripheral circuit unit 50.

The row decoder 20 is a decode circuit of a row address RA (block address BA). The row decoder 20 is coupled to the input/output circuit 40, an address register 51, a row driver 55, and the memory cell array 100. The row decoder 20 selects one of the blocks BLK in the memory cell array 100 based on a decoding result of the row address RA (block address BA). The row decoder 20 applies voltages to interconnects in a row direction of the selected block BLK (word lines and select gate lines to be described later).

The sense amplifier 30 is a circuit that writes and reads the data DT. The sense amplifier 30 is coupled to the input/output circuit 40, the address register 51, a column driver 56, and the memory cell array 100. The sense amplifier 30 reads the data DT from the memory cell array 100 during the read operation. In addition, the sense amplifier 30 supplies voltages based on write data DT to the memory cell array 100 during the write operation. The sense amplifier 30 can apply voltages to interconnects in a column direction (bit lines to be described later).

The input/output circuit 40 is a circuit that inputs and outputs the signal DQ and various control signals. The input/output circuit 40 is coupled to the memory controller 2 via the external coupling terminals PD. In addition, the input/output circuit 40 is coupled to the address register 51, a command register 52, a sequencer 53, and the sense amplifier 30.

In a case where the input signal DQ is the data DT (write data), the input/output circuit 40 receives the input signal DQ based on the timing signals DQS and DQSn. Then, the input/output circuit 40 transmits the data DT to the sense amplifier 30. In addition, the input/output circuit 40 outputs the data DT (read data) to the memory controller 2 together with the timing signals DQS and DQSn.

In a case where the input signal DQ is the memory address ADD, the input/output circuit 40 transmits the memory address ADD to the address register 51. In addition, in a case where the input signal DQ is the command CMD, the input/output circuit 40 transmits the command CMD to the command register 52.

The input/output circuit 40 transmits various control signals received from the memory controller 2 to the sequencer 53.

The input/output circuit 40 transmits the ready/busy signal RBn received from the sequencer 53 to the memory controller 2.

The peripheral circuit unit 50 controls an operation in the memory cell array 100. The peripheral circuit unit 50 includes the address register 51, the command register 52, the sequencer 53, a voltage generator 54, the row driver 55, and the column driver 56.

The address register 51 is a register that temporarily stores the memory address ADD. The address register 51 is coupled to the input/output circuit 40, the row driver 55, the row decoder 20, and the sense amplifier 30. The address register 51 receives the memory address ADD from the input/output circuit 40. For example, the memory address ADD includes the row address RA and a column address CA. The row address RA is an address designating an interconnect in the row direction of the memory cell array 100. The column address CA is an address designating an interconnect in the column direction of the memory cell array 100. For example, the row address RA includes the block address BA and a page address PA. For example, the block address BA is used for selection between the blocks BLK. Hereinafter, one of the blocks BLK that has been selected is referred to as a “selected block BLK”. In addition, one of the blocks BLK that has not been selected is referred to as a “non-selected block BLK”. The page address PA is used for selection among the interconnects (word lines and select gate lines) in the row direction. The column address CA is used for selection among the interconnects (bit lines) in the column direction. For example, the address register 51 transmits the page address PA to the row driver 55. The address register 51 transmits the block address BA to the row decoder 20. The address register 51 transmits the column address CA to the sense amplifier 30.

The command register 52 is a register that temporarily stores the command CMD. The command register 52 is coupled to the input/output circuit 40 and the sequencer 53. The command register 52 transfers the command CMD to the sequencer 53.

The sequencer 53 is a circuit that controls the entire operation of the semiconductor memory device 1. The sequencer 53 may function as a controller of the semiconductor memory device 1. For example, the sequencer 53 is coupled to the input/output circuit 40, the command register 52, the voltage generator 54, the row driver 55, the column driver 56, the row decoder 20, and the sense amplifier 30. For example, the sequencer 53 controls the voltage generator 54, the row driver 55, the column driver 56, the row decoder 20, and the sense amplifier 30. For example, the sequencer 53 executes a write operation, a read operation, an erase operation, and the like based on the command CMD.

The voltage generator 54 generates voltages used for the write operation, the read operation, and the erase operation based on the control of the sequencer 53. The voltage generator 54 is coupled to the sequencer 53, the row driver 55, and the column driver 56. The voltage generator 54 supplies voltages to the row driver 55 and the column driver 56.

The row driver 55 is a driver that supplies voltages to the row decoder 20. The row driver 55 is coupled to the sequencer 53, the voltage generator 54, and the row decoder 20. For example, the row driver 55 supplies voltages to the row decoder 20 based on the row address RA (page address PA).

The column driver 56 is a driver that supplies voltages to the sense amplifier 30. The column driver 56 is coupled to the sequencer 53, the voltage generator 54, and the sense amplifier 30. For example, the column driver 56 supplies voltages to the sense amplifier 30.

### 1.1.2 Circuit Configuration of Memory Cell Array

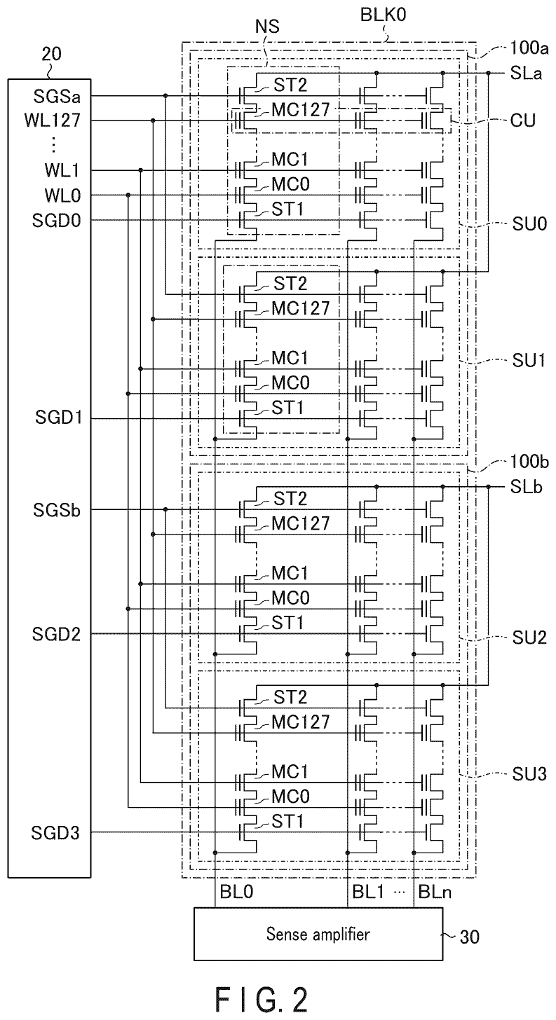

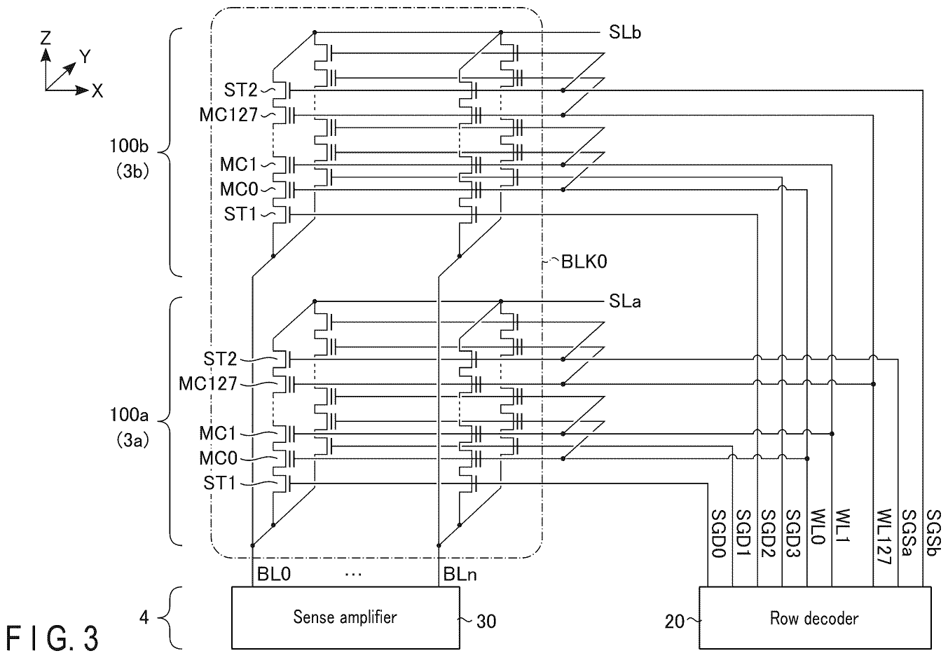

Next, an example of a circuit configuration of the memory cell array 100 will be described with reference to FIGS. 2 and 3. FIG. 2 is a plan view illustrating a circuit configuration of the memory cell array 100.

FIG. 3 is a perspective view illustrating the circuit configuration of the memory cell array 100. Although the example of FIGS. 2 and 3 illustrates the circuit configuration of the block BLK0, the same applies to the other block BLK. Hereinafter, a direction in which word lines WL extend in the array chips 3 is referred to as an X direction. A direction which intersects with the X direction and in which bit lines BL extend is referred to as a Y direction. A direction intersecting the X direction and the Y direction and in which the array chips 3a and 3b and the circuit chip 4 are stacked is referred to as a Z direction.

As shown in FIG. 2, for example, the block BLK0 includes the four string units SU0 to SU3. More specifically, the memory cell array 100a includes the string units SU0 and SU1 of the block BLK0. The memory cell array 100b includes the string units SU2 and SU3 of the block BLK0.

Each of the string units SU includes the plurality of NAND strings NS.

Each of the NAND strings NS includes a plurality of memory cell transistors MC and selection transistors ST1 and ST2. In the example of FIG. 2, each NAND string NS includes 128 memory cell transistors MC0 to MC127. Note that the number of memory cell transistors MC included in the NAND string NS is arbitrary.

The memory cell transistors MC store data in a non-volatile manner. Each of the memory cell transistors MC includes a control gate and a charge storage layer. The memory cell transistors MC may be of a metal-oxide-nitride-oxide-silicon (MONOS) type or of a floating gate (FG) type. In the MONOS type, an insulating layer is used as the charge storage layer. In the FG type, a conductor is used as the charge storage layer. Hereinafter, a case where the memory cell transistors MC are of the MONOS type will be described.

The selection transistors ST1 and ST2 are used to select the string units SU during various operations. Hereinafter, one of the string units SU that has been selected is referred to as a “selected string unit SU”. In addition, one of the string units SU that has not been selected is referred to as a “non-selected string units SU”. The number of the selection transistors ST1 and ST2 is arbitrary. One or more selection transistors ST1 and ST2 may be included in each of the NAND strings NS.

Current paths of the memory cell transistors MC and the selection transistors ST1 and ST2 in each NAND string NS are coupled in series. In the example of FIG. 2, the current paths of the selection transistor ST1, the memory cell transistors MC0 to MC127, and the selection transistor ST2 are coupled in series in this order from a lower side to an upper side in the drawing. That is, the selection transistor ST1, the memory cell transistors MC0 to MC127, and the selection transistor ST2 are sequentially coupled from the bit lines BL to a source line SL. A drain of the selection transistor ST1 is coupled to one of the bit lines BL. A source of the selection transistor ST2 is coupled to the source line SL.

Control gates of the plurality of memory cell transistors MC0 to MC127 in the block BLK are commonly coupled to the word lines WL0 to WL127, respectively. Each word line WL is commonly coupled to the memory cell transistors MC of the memory cell array 100a and the memory cell transistors MC of the memory cell array 100b. That is, the memory cell array 100a (array chip 3a) and the memory cell array 100b (array chip 3b) share the word line WL.

In the example of FIG. 2, the memory cell transistors MC0 of the block BLK0 provided in the memory cell arrays 100a and 100b are commonly coupled to the word line WL0. Similarly, the other memory cell transistors MC1 to MC127 are coupled to the corresponding word lines WL1 to WL127, respectively. In other words, the memory cell array 100a (array chip 3a) and the memory cell array 100b (array chip 3b) share the word lines WL0 to WL127.

In each block BLK, gates of the plurality of selection transistors ST1 in the string unit SU are commonly coupled to one select gate line SGD. In the example of FIG. 2, the gates of the plurality of selection transistors ST1 in the string unit SU0 are commonly coupled to a select gate line SGD0. Similarly, the gates of the plurality of selection transistors ST1 in the string unit SU1 are commonly coupled to a select gate line SGD1. The gates of the plurality of selection transistors ST1 in the string unit SU2 are commonly coupled to a select gate line SGD2. The gates of the plurality of selection transistors ST1 in the string unit SU3 are commonly coupled to a select gate line SGD3.

In each block BLK, gates of the plurality of selection transistors ST2 in the plurality of string units SU of the memory cell array 100a (array chip 3a) are commonly coupled to one select gate line SGS. Similarly, the gates of the plurality of selection transistors ST2 in the plurality of string units SU of the memory cell array 100b (array chip 3b) are commonly coupled to one select gate line SGS. Hereinafter, the select gate line SGS coupled to the selection transistors ST2 of the memory cell array 100a and not coupled to the selection transistors ST2 of the memory cell array 100b will be referred to as a “select gate line SGSa”. The select gate line SGS coupled to the selection transistors ST2 of the memory cell array 100b and not coupled to the selection transistors ST2 of the memory cell array 100a will be referred to as a “select gate line SGSb”. In the example of FIG. 2, the gates of the plurality of selection transistors ST2 in the string units SU0 and SU1 are commonly coupled to the select gate line SGSa. Similarly, the gates of the plurality of selection transistors ST2 in the string units SU2 and SU3 are commonly coupled to the select gate line SGSb. That is, the memory cell array 100a and the memory cell array 100b do not share the select gate lines SGS. The memory cell array 100a and the memory cell array 100b may share the select gate lines SGS. Alternatively, similarly to the select gate line SGD, the select gate line SGS may be provided for each string unit SU.

The word lines WL and the select gate lines SGD and SGS are coupled to the row decoder 20.

Drains of the plurality of selection transistors ST1 in the string unit SU are coupled to different bit lines BL. In other words, the bit lines BL are commonly coupled to one NAND string NS in each string unit SU of each block BLK. That is, the memory cell array 100a and the memory cell array 100b share the bit lines BL. The same column address CA is assigned to the plurality of NAND strings NS coupled to one bit line BL. In the example of FIG. 2, each string unit SU includes n+1 NAND strings NS (n is an integer of 0 or more). That is, the string unit SU includes n+1 selection transistors ST1. The drains of the n+1 selection transistors ST1 in the string unit SU are coupled to the n+1 bit lines BL0 to BLn, respectively. The bit lines BL0 to BLn are coupled to the sense amplifier 30, respectively.

The plurality of string units SU of the plurality of blocks BLK of the memory cell array 100a (array chip 3a) are commonly coupled to one source line SL. That is, the sources of the plurality of selection transistors ST2 in the memory cell array 100a are commonly coupled to one source line SL. Similarly, the plurality of string units SU of the plurality of blocks BLK of the memory cell array 100b (array chip 3b) are commonly coupled to one source line SL. That is, the sources of the plurality of selection transistors ST2 in the memory cell array 100b are commonly coupled to one source line SL. Hereinafter, in a case where the source line SL coupled to the selection transistors ST2 of the memory cell array 100a and not coupled to the selection transistors ST2 of the memory cell array 100b are specified, these are referred to as a “source line SLa”. In a case where the source line SL coupled to the selection transistors ST2 of the memory cell array 100b and not coupled to the selection transistors ST2 of the memory cell array 100a are specified, these are referred to as a “source line SLb”. The memory cell array 100a and the memory cell array 100b may share the source line SL.

Hereinafter, a set of the memory cell transistors MC coupled to one word line WL in one string unit SU is referred to as a “cell unit CU”. For example, in a case where a memory cell transistor MC stores one bit data, a storage capacity of the cell unit CU is defined as “one page data”. The cell unit CU may have a storage capacity of two page data or more based on the number of bits of data stored in the memory cell transistor MC.

As illustrated in FIG. 3, an array region (string units SU2 and SU3) of the block BLK0 of the memory cell array 100b is disposed above an array region (string units SU0 and SU1) of the block BLK0 of the memory cell array 100a. In other words, the array region of the block BLK0 of the array chip 3b and the array region of the block BLK0 of the array chip 3a are arranged side by side in the Z direction. That is, the NAND string NS of the memory cell array 100a and the NAND string NS of the memory cell array 100b arranged above the NAND string NS of the memory cell array 100a are included in the same block BLK. In the example of FIG. 3, in each of the memory cell arrays 100a and 100b, the memory cell transistors MC arranged side by side in the X direction and the Y direction are commonly coupled to one word line WL. In each of the memory cell arrays 100a and 100b, the NAND strings NS arranged side by side in the Y direction are commonly coupled to the bit line BL. Further, the NAND string NS of the memory cell array 100a and the NAND string NS of the memory cell array 100b arranged side by side in the Z direction are commonly coupled to one bit line BL.

### 1.1.3 Circuit Configuration of Row Decoder

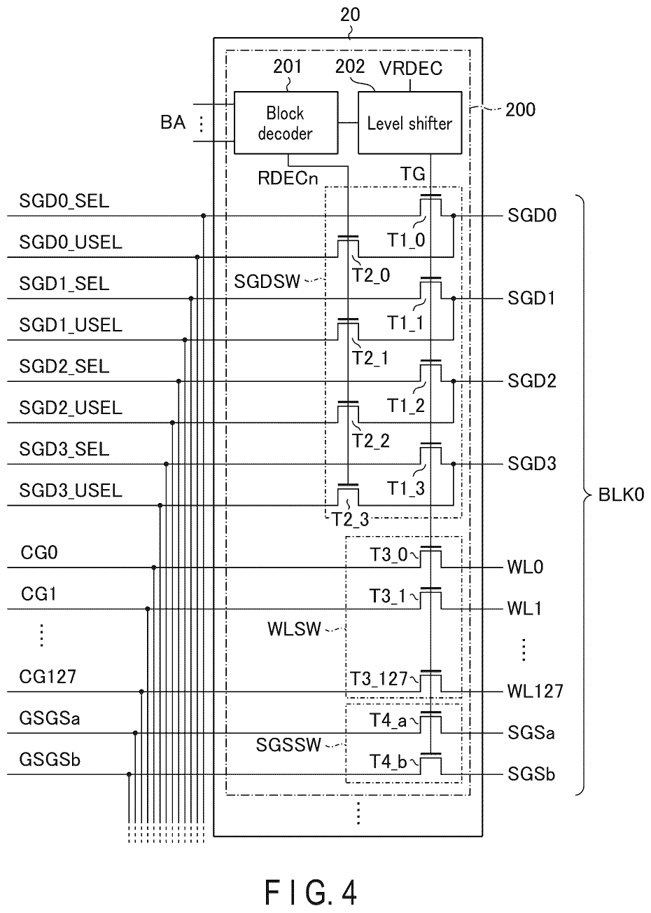

Next, a circuit configuration of the row decoder 20 will be described with reference to FIG. 4. FIG. 4 is a circuit diagram of the row decoder 20. In the following description, in a case where an end of a transistor is limited to neither of the source and the drain, one of the source and the drain of the transistor is referred to as “one end of the transistor”, and the other of the source and the drain of the transistor is referred to as “the other end of the transistor”.

As illustrated in FIG. 4, the row decoder 20 includes a plurality of row decoder units 200 provided for each of the blocks BLK. Although the example of FIG. 4 illustrates one of the row decoder units 200 corresponding to the block BLK0, the other one of the row decoder units 200 corresponding to the other block BLK has the same configuration.

The row decoder unit 200 includes a block decoder 201, a level shifter 202, a WL switch circuit group WLSW, an SGD switch circuit group SGDSW, and an SGS switch circuit group SGSSW.

The block decoder 201 decodes the block address BA. The block decoder 201 is coupled to the level shifter 202. Furthermore, the block decoder 201 is coupled to a plurality of switch circuits (transistors T2) of the SGD switch circuit group SGDSW via a signal line RDECn. Note that the SGD switch circuit group SGDSW may be coupled to the level shifter 202 via the signal line RDECn. The block decoder 201 transmits a result (signal) obtained by decoding the block address BA to the level shifter 202 and the SGD switch circuit group SGDSW. In a case where the block address BA is the address of the corresponding block BLK, the block decoder 201 transmits a high (“H”) level signal to the level shifter 202 and transmits a low (“L”) level signal to the SGD switch circuit group SGDSW. On the other hand, in a case where the block address BA is not the address of the corresponding block BLK, the block decoder 201 transmits an “L” level signal to the level shifter 202, and transmits an “H” level signal to the SGD switch circuit group SGDSW.

The level shifter 202 shifts a level of a potential of the signal received from the block decoder 201. For example, the level shifter 202 shifts the level of the voltage (potential) of the “H” level signal received from the block decoder 201 to the voltage VRDEC. The level shifter 202 is coupled to a plurality of switch circuits (transistors T3) of the WL switch circuit group WLSW, a plurality of switch circuits (transistors T1) of the SGD switch circuit group SGDSW, and a plurality of switch circuits (transistors T4) of the SGS switch circuit group SGSSW via a signal line TG.

The SGD switch circuit group SGDSW is a set of a plurality of switch circuits for controlling coupling between the row driver 55 and the plurality of select gate lines SGD. The SGD switch circuit group SGDSW includes a plurality of high-withstand-voltage n-channel MOS transistors T1 and a plurality of high-withstand-voltage n-channel MOS transistors T2. The transistors T1 and T2 function as switch circuits for controlling coupling between the row driver 55 and the select gate line SGD, respectively. The transistor T1 is controlled based on a voltage of a signal applied via the signal line TG. In addition, the transistor T2 is controlled based on a voltage of a signal applied via the signal line RDECn. In the example of FIG. 4, the SGD switch circuit group SGDSW includes transistors T1_0 to T1_3 and T2_0 to T2_3. The number and the arrangement of the transistors T1 and T2 are designed based on the configuration of the select gate line SGD.

One end of the transistor T1_0 is coupled to the select gate line SGD0. The other end of the transistor T1_0 is coupled to the row driver 55 via an interconnect line SGD0_SEL. A gate of the transistor T1_0 is coupled to the signal line TG.

One end of the transistor T2_0 is coupled to the select gate line SGD0. The other end of the transistor T2_0 is coupled to the row driver 55 via an interconnect SGD0 USEL. A gate of the transistor T2_0 is coupled to the signal line RDECn.

One end of the transistor T1_1 is coupled to the select gate line SGD1. The other end of the transistor T1_1 is coupled to the row driver 55 via an interconnect SGD1_SEL. A gate of the transistor T1_1 is coupled to the signal line TG.

One end of the transistor T2_1 is coupled to the select gate line SGD1. The other end of the transistor T2_1 is coupled to the row driver 55 via the interconnect SGD1_USEL. A gate of the transistor T2_1 is coupled to the signal line RDECn.

One end of the transistor T1_2 is coupled to the select gate line SGD2. The other end of the transistor T1_2 is coupled to the row driver 55 via the interconnect SGD2 SEL. A gate of the transistor T1_2 is coupled to the signal line TG.

One end of the transistor T2_2 is coupled to the select gate line SGD2. The other end of the transistor T2_2 is coupled to the row driver 55 via the interconnect SGD2_USEL. A gate of the transistor T2_2 is coupled to the signal line RDECn.

One end of the transistor T1_3 is coupled to the select gate line SGD3. The other end of the transistor T1_3 is coupled to the row driver 55 via the interconnect SGD3_SEL. A gate of the transistor T1_3 is coupled to the signal line TG.

One end of the transistor T2_3 is coupled to the select gate line SGD3. The other end of the transistor T2_3 is coupled to the row driver 55 via the interconnect SGD3 USEL. A gate of the transistor T2_3 is coupled to the signal line RDECn.

The row driver 55 applies a voltage corresponding to the selected block BLK to the interconnects SGD0_SEL to SGD3_SEL. In addition, the row driver 55 applies a voltage corresponding to the non-selected block BLK to the interconnects SGD0_USEL to SGD3_USEL.

The WL switch circuit group WLSW is a set of a plurality of switch circuits for controlling coupling between the row driver 55 and the plurality of word lines WL. The WL switch circuit group WLSW includes a plurality of high-withstand-voltage n-channel MOS transistors T3. The transistors T3 function as switch circuits that control coupling between the row driver 55 and the word lines WL. The transistor T3 is controlled based on a voltage of a signal applied via the signal line TG. In the example of FIG. 4, the WL switch circuit group WLSW includes transistors T3_0 to T3_127. The number and the arrangement of the transistors T3 are designed based on the configuration of the word lines WL.

One end of the transistor T3_0 is coupled to the word line WL0. The other end of the transistor T3_0 is coupled to the row driver 55 via an interconnect CG0. A gate of the transistor T3_0 is coupled to the signal line TG.

The transistors T3_1 to T3_127 are similarly coupled. For example, one end of the transistor T3_1 is coupled to the word line WL1. The other end of the transistor T3_1 is coupled to the row driver 55 via an interconnect CG1. A gate of the transistor T3_1 is coupled to the signal line TG.

The row driver 55 applies voltages corresponding to the selected block BLK to the interconnects CG0 to CG127.

The SGS switch circuit group SGSSW is a set of a plurality of switch circuits for controlling coupling between the row driver 55 and the plurality of select gate lines SGS. The SGS switch circuit group SGSSW includes a plurality of high-withstand-voltage n-channel MOS transistors T4. The transistors T4 function as switch circuits that control coupling between the row driver 55 and the select gate lines SGS. The transistor T4 is controlled based on a voltage of a signal applied via the signal line TG. In the example of FIG. 4, the SGS switch circuit group SGSSW includes two high-withstand-voltage n-channel MOS transistors T4_a and T4 b. The number and the arrangement of the transistors T4 are designed based on the configuration of the select gate line SGS.

One end of the transistor T4_a is coupled to the select gate line SGSa. The other end of the transistor T4_a is coupled to the row driver 55 via an interconnect GSGSa. A gate of the transistor T4_a is coupled to the signal line TG.

One end of the transistor T4_b is coupled to the select gate line SGSb. The other end of the transistor T4_b is coupled to the row driver 55 via an interconnect GSGSb. A gate of the transistor T4_b is coupled to the signal line TG.

The row driver 55 applies a voltage corresponding to the selected block BLK to the interconnects GSGSa and GSGSb.

For example, in the write operation, the read operation, or the erase operation, in a case where the block address BA matches the corresponding block BLK0, the block decoder 201 transmits the “H” level signal to the level shifter 202, and applies the “L” level voltage (for example, the ground voltage Vss) to the signal line RDECn. As a result, the level shifter 202 applies the voltage VRDEC to the signal line TG as a voltage at the “H” level. In addition, in a case where the block address BA does not match the corresponding block BLK0, the block decoder 201 transmits an “L” level signal to the level shifter 202 and applies an “H” level voltage to the signal line RDECn. As a result, the level shifter 202 applies a voltage at the “L” level to the signal line TG. In a case where the voltage at the “H” level is applied to the signal line TG, the transistors T1, T3, and T4 are turned on. In addition, in a case where the voltage at the “H” level is applied to the signal line RDECn, the transistors T2 are turned on. The voltage at the “H” level applied to the signal line RDECn is lower than the voltage at the “H” level (voltage VRDEC) applied to the signal line TG.

### 1.1.4 Arrangement of Chips

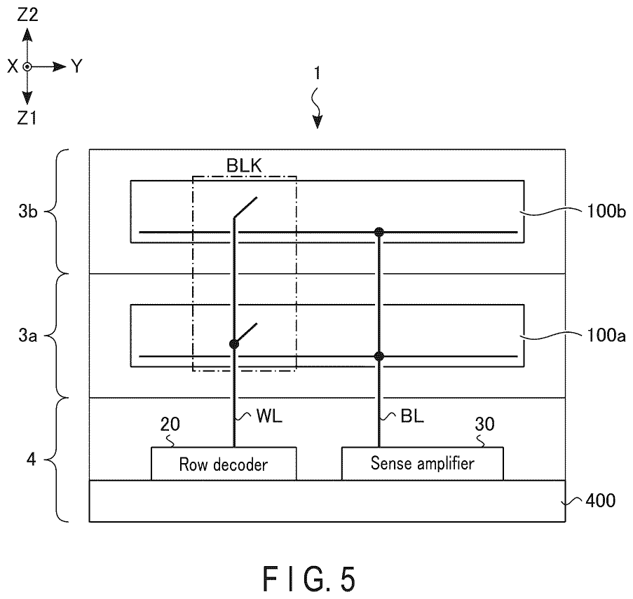

Next, an example of the arrangement of the chips will be described with reference to FIG. 5. FIG. 5 is a cross-sectional view illustrating the arrangement of the array chips 3a and 3b and the circuit chip 4. In the example of FIG. 5, one word line WL and one bit line BL are illustrated in order to simplify the description. The select gate lines SGD and SGS and the source lines SL are omitted.

Hereinafter, in a case where the Z direction is specified, a direction from the array chip 3 toward the circuit chip 4 is referred to as a Z1 direction, and a direction facing the Z1 direction is referred to as a Z2 direction.

As illustrated in FIG. 5, the array chip 3a is bonded onto the circuit chip 4 in the Z2 direction. Then, the array chip 3b is bonded onto the array chip 3a. In other words, the circuit chip 4 is bonded to a surface of the array chip 3a facing the Z1 direction. Then, the array chip 3b is bonded to a surface of the array chip 3a facing the Z2 direction. That is, the circuit chip 4, the array chip 3a, and the array chip 3b are sequentially stacked in the Z2 direction.

The row decoder 20 and the sense amplifier 30 are provided on the semiconductor substrate 400 of the circuit chip 4.

The array chips 3a and 3b are respectively provided with the memory cell arrays 100a and 100b.

A part of the memory cell array 100a and a part of the memory cell array 100b arranged side by side in the Z direction constitute the block BLK. The word line WL is shared between the memory cell array 100a and the memory cell array 100b. The bit lines BL are shared by the memory cell array 100a and the memory cell array 100b.

### 1.1.5 Arrangement of Memory Cell Arrays

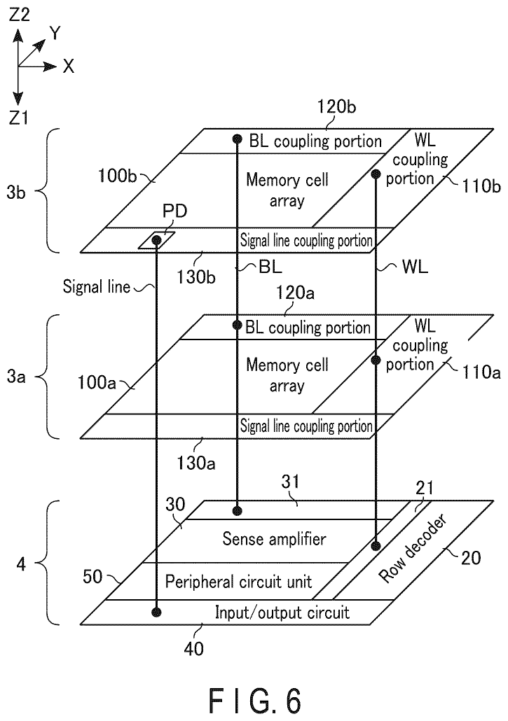

Next, an example of the arrangement of the memory cell array 100 will be described with reference to FIG. 6. FIG. 6 is a perspective view illustrating the arrangement of the array chips 3a and 3b and the circuit chip 4. In the example of FIG. 6, one word line WL, one bit line BL, and one signal line (for example, a signal line that transfers the signal DQ) are illustrated in order to simplify the illustration. The select gate lines SGD and SGD and the source lines SL are omitted.

As illustrated in FIG. 6, the array chip 3a includes the memory cell array 100a, a WL coupling portion 110a, a BL coupling portion 120a, and a signal coupling portion 130a. Similarly, the array chip 3b includes the memory cell array 100b, a WL coupling portion 110b, a BL coupling portion 120b, and a signal coupling portion 130b.

The WL coupling portions 110a and 110b are regions where contact plugs, interconnects, and the like for coupling the word lines WL and the select gate lines SGD and SGS to the row decoder 20 are provided.

In the example of FIG. 6, the WL coupling portion 110a is arranged adjacent to the memory cell array 100a in the X direction. The word lines WL provided in the memory cell array 100a are drawn to the WL coupling portion 110a. In the WL coupling portion 110a, the word line WL provided in the memory cell array 100a is coupled to a contact plug electrically coupled to the row decoder 20. Note that the arrangement of the WL coupling portion 110a is arbitrary. For example, a plurality of WL coupling portions 110a may be provided. The WL coupling portion 110a may also be provided in the memory cell array 100a.

Similarly, the WL coupling portion 110b is arranged adjacent to the memory cell array 100b in the X direction. Further, the WL coupling portion 110b is disposed above the WL coupling portion 110a. The word lines WL provided in the memory cell array 100b are drawn to the WL coupling portion 110b. In the WL coupling portion 110b, the word line WL provided in the memory cell array 100b is coupled to a contact plug electrically coupled to the row decoder 20. Note that the arrangement of the WL coupling portion 110b is arbitrary. For example, a plurality of WL coupling portions 110b may be provided. The WL coupling portion 110b may also be provided in the memory cell array 100b.

For example, the word line WL is coupled to the row decoder 20 via the WL coupling portions 110a and 110b. For example, the word line WL provided in the memory cell array 100a and the word line WL provided in the memory cell array 100b are electrically coupled in the WL coupling portion 110a.

The BL coupling portions 120a and 120b are regions where contact plugs, interconnects, and the like for coupling the bit lines BL and the sense amplifier 30 are provided.

In the example of FIG. 6, the BL coupling portion 120a is arranged adjacent to the memory cell array 100a in the Y direction. The bit lines BL provided in the memory cell array 100a are drawn to the BL coupling portion 120a. In the BL coupling portion 120a, the bit line BL provided in the memory cell array 100a is coupled to a contact plug electrically coupled to the sense amplifier 30. The arrangement of the BL coupling portion 120a is arbitrary. For example, a plurality of the BL coupling portions 120a may be provided.

Similarly, the BL coupling portion 120b is arranged adjacent to the memory cell array 100b in the Y direction. Further, the BL coupling portion 120b is disposed above the BL coupling portion 120a. The bit lines BL provided in the memory cell array 100b are drawn to the BL coupling portion 120b. In the BL coupling portion 120b, the bit line BL provided in the memory cell array 100b is coupled to a contact plug electrically coupled to the sense amplifier 30. The arrangement of the BL coupling portion 120b is arbitrary. For example, a plurality of the BL coupling portions 120b may be provided.

The bit line BL is coupled to the sense amplifier 30 via the BL coupling portions 120a and 120b. For example, the bit line BL of the memory cell array 100a and the bit line BL of the memory cell array 100b are electrically coupled in the BL coupling portion 120a.

The signal coupling portions 130a and 130b are regions where signal lines (contact plugs, interconnects, and the like) for coupling the external coupling terminals PD and the input/output circuit 40 are provided. In the example of FIG. 6, the signal coupling portion 130a is provided at an end of the array chip 3a in the Y direction. Similarly, the signal coupling portion 130b is provided at an end of the array chip 3b in the Y direction. For example, the input/output circuit 40 and the signal coupling portions 130a and 130b are arranged along the Z direction. Note that the arrangement of the signal coupling portions 130a and 130b is arbitrary. For example, a plurality of the signal coupling portions 130a and 130b may be respectively provided.

The signal coupling portion 130b is provided with the external coupling terminals PD. For example, the external coupling terminals PD is coupled to the input/output circuit 40 via signal lines provided in the signal coupling portions 130a and 130b. The signal lines are not electrically coupled to the memory cell arrays 100a and 100b.

The circuit chip 4 includes, for example, a WL hook-up portion 21 and a BL hook-up portion 31.

The WL hook-up portion 21 is a region in which contact plugs, interconnects, and the like for coupling the row decoder 20 to the word lines WL and the select gate lines SGD and SGS are provided. The word lines WL and the select gate lines SGD and SGS are coupled to the row decoder 20 via the WL hook-up portion 21. The WL hook-up portion 21 and the WL coupling portions 110a and 110b are disposed along the Z direction. The row decoder 20 is disposed adjacent to the WL hook-up portion 21. For example, the WL switch circuit group WLSW, the SGD switch circuit group SGDSW, and the SGS switch circuit group SGSSW of the row decoder 20 described with reference to FIG. 4 may be arranged in the WL hook-up portion 21.

The BL hook-up portion 31 is a region where contact plugs, interconnects, and the like for coupling the sense amplifier 30 and the bit lines BL are provided. The bit lines BL are coupled to the sense amplifier 30 via the BL hook-up portion 31. The BL hook-up portion 31 and the BL coupling portions 120a and 120b are disposed along the Z direction. In addition, the sense amplifier 30 is disposed adjacent to the BL hook-up portion 31.

### 1.1.6 Cross-Sectional Configuration of Memory Cell Array

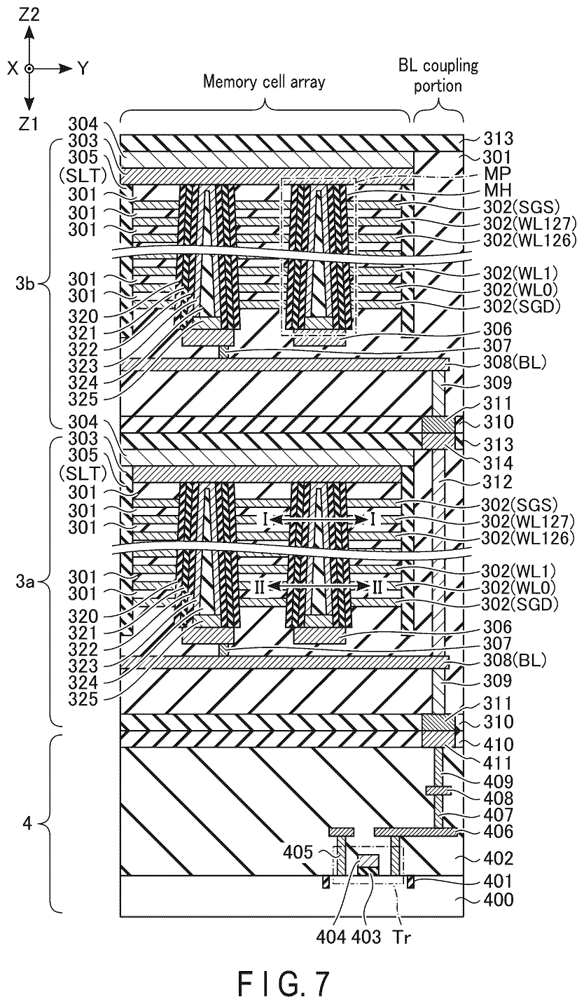

Next, an example of a cross-sectional configuration of the memory cell array 100 will be described with reference to FIG. 7. FIG. 7 is a cross-sectional view of the memory cell array 100.

As illustrated in FIG. 7, the semiconductor memory device 1 has a bonded structure in which the array chip 3a, the array chip 3b, and the circuit chip 4 are bonded. The chips are electrically coupled to each other via electrodes provided on the chips.

First, an internal configuration of the array chip 3a will be described.

The array chip 3a includes the memory cell array 100a and various interconnect layers for coupling to other chips.

The array chip 3a includes insulating layers 301, 305, 310, and 313, interconnect layers 302, 304, and 308, a semiconductor layer 303, and conductors 306, 307, 309, 311, 312, and 314.

In the memory cell array 100a, a plurality of the insulating layers 301 and a plurality of the interconnect layers 302 are alternately stacked one by one. In the example of FIG. 7, 130 interconnect layers 302 functioning as the select gate line SGD, the word lines WL0 to WL127, and the select gate line SGS are sequentially stacked in the Z2 direction.

The insulating layers 301 may contain, for example, silicon oxide (SiO). The interconnect layers 302 include a conductive material. The conductive material may contain a metal material, an n-type semiconductor, or a p-type semiconductor. As the conductive material of the interconnect layers 302, for example, a stacked structure of titanium nitride (TiN) and tungsten (W) is used. In this case, TiN is provided so as to cover W. Note that the interconnect layers 302 may contain a high dielectric constant material such as aluminum oxide (AlO). In this case, the high dielectric constant material is provided so as to cover the conductive material.

For example, the plurality of interconnect layers 302 are separated for each block BLK by a member SLT extending in the X direction. The member SLT includes the insulating layer 305. The insulating layer 305 may contain SiO. Note that the member SLT may include a conductor electrically coupled to the semiconductor layer 303 and not electrically coupled to the interconnect layers 302. In this case, the insulating layer 305 is provided so as to surround a side surface of the member SLT. Then, an interior of the insulating layer 305 is filled with the conductor.

In the Z2 direction, the semiconductor layer 303 is provided above the interconnect layer 302 functioning as the select gate line SGS. The insulating layer 301 is provided between the interconnect layer 302 and the semiconductor layer 303. The semiconductor layer 303 functions as the source line SL. In the Z2 direction, the interconnect layer 304 is provided on the semiconductor layer 303. The interconnect layer 304 is used as an interconnect layer for electrically coupling the semiconductor layer 303 to other chips. The interconnect layer 304 includes a conductive material. The conductive material may contain a metal material, an n-type semiconductor, or a p-type semiconductor. For example, the interconnect layer 304 contains aluminum (Al).

The memory cell array 100a is provided with a plurality of memory pillars MP. For example, the memory pillars MP have a substantially columnar shape extending in the Z direction. One memory pillar MP corresponds to one NAND string NS. The memory pillar MP penetrates (passes) the plurality of interconnect layers 302. An end of the memory pillar MP in the Z2 direction is in contact with the semiconductor layer 303. That is, one end of the memory pillar MP is coupled to the source line SL.

In the Z1 direction, the conductor 306 is provided on an end of the memory pillar MP. For example, the conductor 306 has a substantially columnar shape. The conductor 306 functions as a contact plug. A conductor 307 is provided on the conductor 306. For example, the conductor 307 has a substantially columnar shape. The conductor 307 functions as a contact plug. In the Z1 direction, a plurality of interconnect layers 308 are provided above the memory pillars MP. The interconnect layers 308 extend in the Y direction. The plurality of interconnect layers 308 are arranged side by side in the X direction. The interconnect layers 308 function as the bit lines BL. The interconnect layers 308 are electrically coupled to one of the memory pillars MP via the conductors 306 and 307. That is, the other end of the memory pillar MP is coupled to the bit lines BL. The conductors 306 and 307 and the interconnect layers 308 may contain a metal material such as W, Al, or copper (Cu).

In the Z1 direction, a conductor 309 is provided on the interconnect layer 308. In other words, in the BL coupling portion 120a, the interconnect layer 308 (bit line BL) is coupled to the conductor 309. For example, the conductor 309 has a substantially columnar shape. The conductor 309 functions as a contact plug. The conductors 309 may contain a metal material such as W, Al, or Cu.

In the Z1 direction, an insulating layer 310 is provided on the insulating layer 301. The insulating layer 310 may contain SiO.

A plurality of conductors 311 are provided in the same layer as the insulating layer 310. The conductor 311 functions as an electrode for electrical coupling with another chip. The conductors 311 may contain Cu.

In the Z1 direction, the conductor 311 is provided on the conductor 309.

Note that a plurality of interconnect layers may be provided between the conductors 311 and the interconnect layers 308.

In the Z2 direction, a conductor 312 is provided on the interconnect layer 308. In other words, in the BL coupling portion 120a, the interconnect layer 308 (bit line BL) is coupled to the conductor 312. For example, the conductor 312 has a substantially columnar shape.

The conductor 312 functions as a contact plug. The conductors 312 may contain a metal material such as W, Al, or Cu.

In the Z2 direction, an insulating layer 313 is provided above the interconnect layer 304 and the insulating layer 301. The insulating layer 313 may contain SiO.

A plurality of conductors 314 are provided in the same layer as the insulating layer 313. The conductor 314 functions as an electrode for electrical coupling with another chip. The conductors 314 may contain Cu.

In the Z2 direction, the conductor 314 is provided on the conductor 312.

Next, an internal configuration of the array chip 3b will be described. Hereinafter, differences from the array chip 3a will be mainly described.

In the array chip 3b, the conductors 312 and 314 described in the configuration of the array chip 3a are omitted. Other configurations are the same as those of the array chip 3a. The interconnect layer 308 of the array chip 3b is electrically coupled to the interconnect layer 308 of the array chip 3a via the conductors 309 and 311 of the array chip 3b and the conductors 312 and 314 of the array chip 3a.

Next, the circuit chip 4 will be described.

The circuit chip 4 includes a plurality of transistors Tr and various interconnect layers. The plurality of transistors Tr are used for the row decoder 20, the sense amplifier 30, and the like.

More specifically, the circuit chip 4 includes a semiconductor substrate 400, insulating layers 401, 402, and 410, a gate insulating film 403, a gate electrode 404, conductors 405, 407, 409, and 411, and interconnect layers 406 and 408.

Isolation regions are provided in the vicinity of a surface of the semiconductor substrate 400. The isolation regions electrically isolate the n-type well region and the p-type well region provided in the vicinity of the surface of the semiconductor substrate 400, for example. The isolation regions are filled with the insulating layers 401. The insulating layers 401 may contain SiO.

The insulating layer 402 is provided on the semiconductor substrate 400. The insulating layer 402 may contain SiO.

Each of the transistors Tr includes the gate insulating film 403 provided on the semiconductor substrate 400, the gate electrode 404 provided on the gate insulating film 403, and a source and a drain (not illustrated) provided in the semiconductor substrate 400. Each of the source and the drain is electrically coupled to the interconnect layer 406 via the conductor 405. The conductor 405 extends in the Z2 direction. The conductor 405 functions as a contact plug. The conductor 407 is provided on the interconnect layer 406. The conductor 407 extends in the Z2 direction. The conductor 407 functions as a contact plug. The interconnect layer 408 is provided on the conductor 407. The conductor 409 is provided on the interconnect layer 408. The conductor 409 extends in the Z2 direction. The conductor 409 functions as a contact plug. The interconnect layers 406 and 408 are configured by a conductive material. The conductors 405, 407, and 409, and the interconnect layers 406 and 408 may contain a metal material, a p-type semiconductor, or an n-type semiconductor. Note that the number of interconnect layers provided in the circuit chip 4 is arbitrary.

In the Z2 direction, an insulating layer 410 is provided on the insulating layer 402. The insulating layer 410 may contain SiO.

The plurality of conductors 411 are provided in the same layer as the insulating layer 410. The conductor 411 functions as an electrode for electrical coupling with another chip. For example, one conductor 409 is provided on one conductor 411. The conductors 411 may contain Cu. The conductor 411 of the circuit chip 4 is in contact with (electrically coupled to) the conductor 311 of the array chip 3a.

Next, an internal configuration of the memory pillar MP will be described.

The memory pillar MP includes a block insulating film 320, a charge storage layer 321, a tunnel insulating film 322, a semiconductor layer 323, a core layer 324, and a cap layer 325.

More specifically, memory holes MH penetrating (passing through) the plurality of interconnect layers 302 are provided. The memory hole MH corresponds to the memory pillar MP. An end of the memory hole MH in the Z2 direction reaches the semiconductor layer 303. On a side surface of the memory hole MH, the block insulating film 320, the charge storage layer 321, and the tunnel insulating film 322 are laminated in this order from the outside. For example, in a case where the memory hole MH has a cylindrical shape, the block insulating film 320, the charge storage layer 321, and the tunnel insulating film 322 have a cylindrical shape. The semiconductor layer 323 is provided so as to be in contact with a side surface of the tunnel insulating film 322. An end of the semiconductor layer 323 in the Z2 direction is in contact with the semiconductor layer 303. The semiconductor layer 323 is a region in which the channels of the memory cell transistors MC and the selection transistors ST1 and ST2 are provided. Therefore, the semiconductor layer 323 functions as a signal line that couples current paths of the selection transistor ST2, the memory cell transistors MC0 to MC127, and the selection transistor ST1. That is, the memory pillar MP includes the semiconductor layer 323 that passes through the interiors of the plurality of interconnect layers 302 and extends in the Z direction. Inside of the semiconductor layer 323 is filled with the core layer 324. The cap layer 325 whose side surface is in contact with the tunnel insulating film 322 is provided on the end portion of the semiconductor layer 323 and the core layer 324 in the Z1 direction.

The block insulating film 320, the tunnel insulating film 322, and the core layer 324 may contain SiO. The charge storage layer 321 may contain silicon nitride (SiN). The semiconductor layer 323 and the cap layer 325 may contain, for example, polysilicon.

The memory cell transistors MC0 to MC127 are configured by combining the memory pillar MP and the interconnect layers 302 functioning as the word lines WL0 to WL127, respectively. Similarly, the selection transistor ST1 is configured by combining the memory pillar MP and the interconnect layer 302 functioning as the select gate line SGD. The selection transistor ST2 is configured by combining the memory pillar MP and the interconnect layer 302 functioning as the select gate line SGS. In other words, the memory pillar MP includes the memory cell transistors MC and the selection transistors ST1 and ST2.

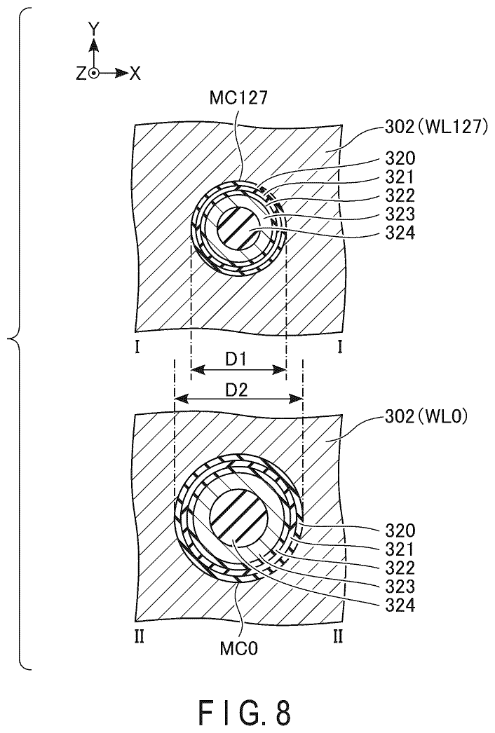

An example of a cross-sectional structure of the memory pillar MP along an XY plane will be described with reference to FIG. 8. FIG. 8 is a cross-sectional view of the memory pillar MP taken along lines I-I and II-II in FIG. 7. More specifically, FIG. 8 illustrates a cross-sectional structure of the memory pillar MP in a layer including the interconnect layer 302 functioning as the word line WL127 and a cross-sectional structure of the memory pillar MP in the layer including the interconnect layer 302 functioning as the word line WL0.

As illustrated in FIG. 8, the core layer 324 is provided, for example, at the central portion of the memory pillar MP. The semiconductor layer 323 surrounds a side surface of the core layer 324. The tunnel insulating film 322 surrounds a side surface of the semiconductor layer 323. The charge storage layer 321 surrounds a side surface of the tunnel insulating film 322. The block insulating film 320 surrounds a side surface of the charge storage layer 321. The interconnect layer 302 surrounds a side surface of the block insulating film 320.

For example, in a manufacturing process of the array chip 3a, the memory hole MH is processed from the bit line BL side toward the source line SL side. In other words, in a case where the memory hole MH is formed, a stacked body including the plurality of interconnect layers 302 and the plurality of insulating layers 301 is processed toward the semiconductor layer 303. At this time, the memory hole MH may be tapered depending on processing characteristics of dry etching. That is, a diameter of the memory hole MH (memory pillar MP) decreases toward the source line SL (Z2 direction). In other words, a cell size (diameter) of the memory cell transistor MC decreases from the bit line BL side toward the source line SL side.

For example, the diameter of the memory pillar MP corresponding to the interconnect layer 302 functioning as the word line WL127, that is, a diameter of the memory cell transistor MC127 is D1. The diameter of the memory pillar MP in the layer including the interconnect layer 302 functioning as the word line WL0, that is, a diameter of the memory cell transistor MC0 is D2. In a case where the memory hole MH has a tapered shape, the diameter D1 and the diameter D2 have a relationship of D1<D2. As described above, in a case where the cell size (diameter) of the memory cell transistor MC is different for each word line WL, the write characteristics of the memory cell transistors MC0 to MC127 vary in the same memory pillar MP.

The plurality of memory pillars MP in the array chip 3 are collectively manufactured. Therefore, the variation in the shape of the plurality of memory pillars MP in the same array chip 3 is relatively small. Therefore, the variation in the cell size of the plurality of memory cell transistors MC coupled to the same word line WL in the array chip 3 is smaller than the variation in the cell size of the memory cell transistors MC0 to MC127. That is, the variation in the write characteristics of the plurality of string units SU (cell units CU) in the array chip 3 coupled to the same word line WL is relatively small.

The array chips 3a and 3b are manufactured separately. Therefore, for example, the variation in the shapes of the memory pillars MP of the array chip 3a and the memory pillars MP of the array chip 3b can be larger than the variation in the shapes of the plurality of memory pillars MP in the same array chip 3. That is, the variation in the write characteristics of the string units SU in the plurality of array chips 3 can be larger than the variation in the write characteristics of the plurality of string units SU in the same array chip 3. In a case where the memory hole MH has a tapered shape in which the diameter decreases toward the source line SL side, the variation in the shape of the memory cell transistor MC by the plurality of array chips 3 can be more remarkable in the memory cell transistor MC on the source line SL side (for example, the memory cell transistor MC127).

### 1.2 Threshold Voltage Distribution of Memory Cell Transistor

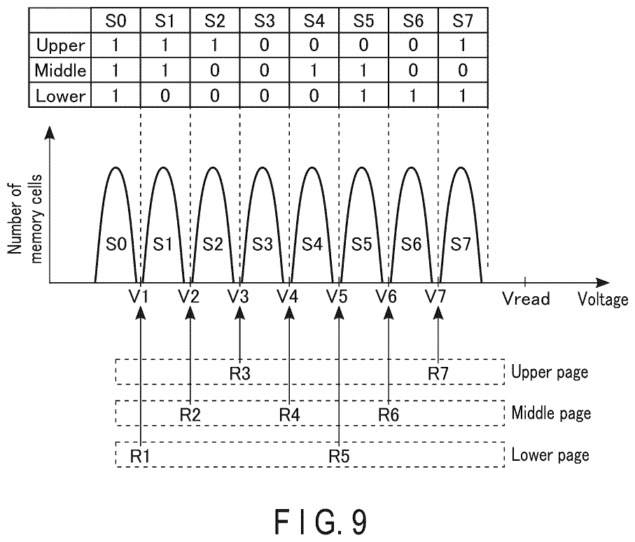

Next, an example of a threshold voltage distribution that can be taken by the memory cell transistors MC will be described with reference to FIG. 9. FIG. 9 is a diagram illustrating the threshold voltage distribution and data allocation in a case where the memory cell transistor MC is a triple level cell (TLC) capable of storing three bit (8-value) data. The number of bits of data that can be stored in the memory cell transistor MC is arbitrary. For example, the memory cell transistor MC may be a single level cell (SLC) capable of storing one bit (binary) data, a multi level cell (MLC) capable of storing two bit (4-value) data, a quad level cell (QLC) capable of storing four bit (16-value) data, or a penta level cell (PLC) capable of storing five bit (32-value) data.

As illustrated in FIG. 9, the threshold voltage of each memory cell transistor MC takes a value included in any of discrete, for example, eight distributions.

Hereinafter, the eight distributions are referred to as an “S0” state, an “S1” state, an “S2” state, an “S3” state, an “S4” state, an “S5” state, an “S6” state, and an “S7” state in an ascending order of the threshold voltage.

The “S0” state corresponds to, for example, a data erase state. The “S1” to “S7” states correspond to a state in which electric charges are injected into the charge storage layer and data is written. In the write operation, verify voltages corresponding to the threshold voltage distributions are V1 to V7. The voltages V1 to V7 have a relationship of V1<V2<V3<V4<V5<V6<V7<Vread. The voltage Vread is a voltage applied to the word line WL that is not selected during the read operation (hereinafter, referred to as a “non-selected word line WL”). In a case where the voltage Vread is applied to the gate of the memory cell transistor MC, the memory cell transistor MC is turned on regardless of stored data.

More specifically, the threshold voltage included in the “S0” state is less than the voltage V1. The threshold voltage included in the “S1” state is equal to or more than the voltage V1 and less than the voltage V2. The threshold voltage included in the “S2” state is equal to or more than the voltage V2 and less than the voltage V3. The threshold voltage included in the “S3” state is equal to or more than the voltage V3 and less than the voltage V4. The threshold voltage included in the “S4” state is equal to or more than the voltage V4 and less than the voltage V5. The threshold voltage included in the “S5” state is equal to or more than the voltage V5 and less than the voltage V6. The threshold voltage included in the “S6” state is equal to or more than the voltage V6 and less than the voltage V7. Further, the threshold voltage included in the “S7” state is equal to or more than the voltage V7 and less than the voltage Vread.

The set value of the read voltage corresponding to each state may be the same as or different from the set value of the verify voltage. Hereinafter, in order to simplify the description, a case where the verify voltage and the read voltage have the same set value will be described.

Hereinafter, the read operation corresponding to the “S1” to “S7” states will be referred to as an R1 read operation, an R2 read operation, an R3 read operation, an R4 read operation, an R5 read operation, an R6 read operation, and an R7 read operation, respectively. In the R1 read operation, it is determined whether or not the threshold voltage of the memory cell transistor MC is less than the voltage V1. In the R2 read operation, it is determined whether or not the threshold voltage of the memory cell transistor MC is less than the voltage V2. In the R3 read operation, it is determined whether or not the threshold voltage of the memory cell transistor MC is less than the voltage V3. The same applies hereinafter.

As described above, each memory cell transistor MC can take eight types of states by having one of the eight threshold voltage distributions. By assigning these states to “000” to “111” in binary notation, each memory cell transistor MC can hold three bit data. Hereinafter, three bits of the data are referred to as a lower bit, a middle bit, and an upper bit, respectively. Further, a set of lower bits collectively written (or read) to the cell unit CU is referred to as a lower page. Similarly, a set of middle bits is referred to as a middle page. Further, a set of upper bits is referred to as an upper page.

In the example of FIG. 9, data is allocated to “upper bit/middle bit/lower bit” for the memory cell transistor MC included in each threshold voltage distribution as follows.
“S0” state: “111” data
“S1” state: “110” data
“S2” state: “100” data
“S3” state: “000” data
“S4” state: “010” data
“S5” state: “011” data
“S6” state: “001” data
“S7” state: “101” data

In the case of reading the data allocated in this manner, the lower bit is determined by the R1 read operation and the R5 read operation. The middle bit is determined by the R2 read operation, the R4 read operation, and the R6 read operation. The upper bit is determined by the R3 read operation and the R7 read operation. That is, the values of the lower bit, the middle bit, and the upper bit are determined by the read operations of two times, three times, and two times, respectively. Hereinafter, this data allocation is referred to as a “2-3-2 code”. Note that the data allocation to the “S0” to “S7” states is not limited to the 2-3-2 code.

### 1.3 Write Operation

Next, the write operation will be described. The write operation includes a program operation and a program verify operation.

The program operation is an operation of increasing a threshold voltage of the memory cell transistor MC by injecting electrons into the charge storage layer (alternatively, the threshold voltage is maintained by hardly injecting electrons into the charge storage layer). Hereinafter, a memory cell transistor MC for increasing the threshold voltage is referred to as a “program-target memory cell transistor MC”. The memory cell transistor MC that does not raise the threshold voltage is referred to as a “program-inhibited memory cell transistor MC”. In the program operation, each memory cell transistor MC is set to be program target or program inhibited based on the write data stored in the sense amplifier 30. For example, in a case where the write data is “0”, the memory cell transistor MC is set as a program target. In a case where the write data is “1”, the memory cell transistor MC is set as program-inhibited.

The program verify operation is an operation of reading data from the memory cell transistor MC and determining whether or not the threshold voltage of the memory cell transistor MC has reached a target level as a target (write target state) after the program operation. Hereinafter, the description of the present embodiment focuses on a method of optimal write voltage adjustment without over-programming. For this purpose, the pass and fail of verification is considered focusing on the memory cell transistor MC whose writing is fastest among the plurality of string units SU in which the writing is performed at the same time. As a result of the program verify operation, the memory cell transistor MC that has not reached the threshold voltage of the write target state is set to the program-target memory cell transistor MC. In addition, the memory cell transistor MC that has reached the threshold voltage of the write target state is set to the program-inhibited memory cell transistor MC.

In the write operation, a combination of the program operation and the program verify operation (hereinafter, referred to as a “program loop”) is repeated. The program voltage applied to the word line WL (hereinafter, referred to as a “selected word line WL”) selected at the time of the program operation increases every time the program loop is repeated. By repetition of the program loop, the threshold voltage of the memory cell transistor MC gradually rises to the target level. The write operation of repeating the program loop while increasing the program voltage as described above is also referred to as an “incremental step-up write operation”.

For example, in a case where the memory cell transistor MC is a TLC, three pages of data (lower page, middle page, and upper page) can be collectively written by the write operation. Hereinafter, the operation of collectively writing a plurality of pages of data corresponding to one cell unit CU is also referred to as a “full-sequence write operation”. For example, in the full-sequence write operation, writing is performed in order from a state having a low threshold voltage by repetition of the program loop.

### 1.3.1 Operation Mode in Write Operation

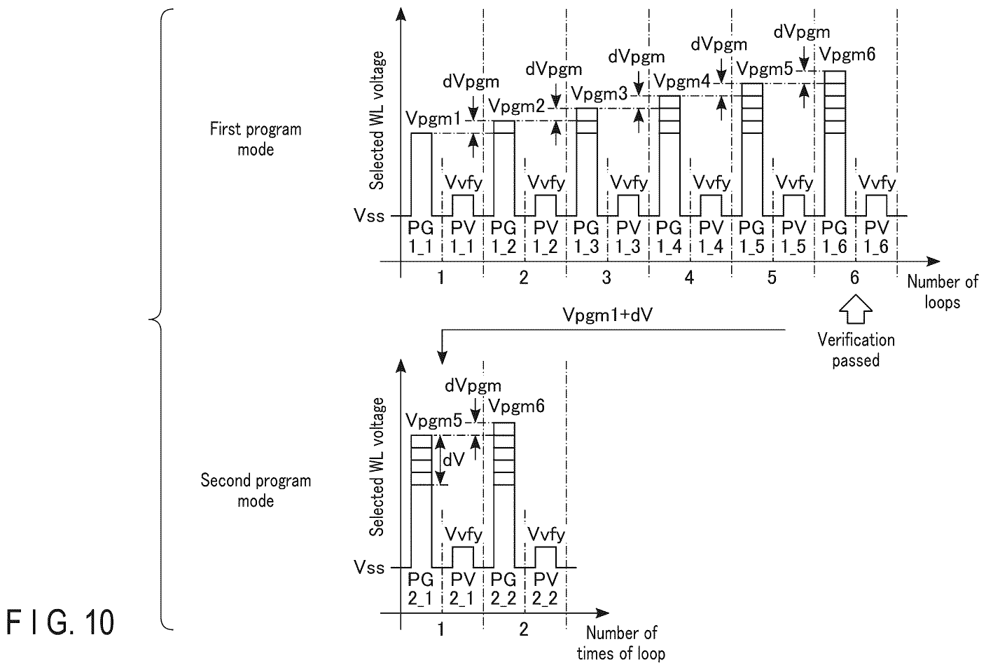

Next, an example of operation modes of the write operation will be described with reference to FIG. 10. FIG. 10 is a diagram illustrating a relationship between the first program mode and the second program mode in the write operation. In the example of FIG. 10, the voltage value applied to the selected word line WL is simplified. The voltage of each interconnect in the write operation will be described later in detail. In addition, the example of FIG. 10 is limited to the write operation corresponding to one state in order to simplify the description. In addition, the example of FIG. 10 illustrates the memory cell transistor MC whose writing is fastest as a representative of the plurality of memory cell transistors MC in the string unit SU in which the writing is performed at the same time.

As illustrated in FIG. 10, the write operation includes a first program mode and a second program mode as operation modes.

The first program mode is an operation mode in which a voltage Vpgm1 set in advance as a program voltage Vpgm is applied to the selected word line WL in a program operation PG of a first time of the program loop.

The second program mode is an operation mode in which a voltage higher than the voltage Vpgm1 is applied to the selected word line WL in the program operation PG of the first time of the program loop. For example, in the second program mode, a voltage (Vpgm1+dV) is applied as the program voltage Vpgm in the program operation PG of the first time of the program loop. A shift voltage dV is a positive voltage value set based on a result of the program verify operation in the first program mode. The shift voltage dV is set to a value at which over-programming does not occur in a first time of the program operation PG. The over-programming is a state in which the threshold voltage of the memory cell transistor MC exceeds the write target state.

Hereinafter, in a case where the program voltage Vpgm in the first program mode is specified, the program voltage is referred to as a “program voltage Vpgmf”. Similarly, in a case where the program voltage in the second program mode is specified, the program voltage is referred to as a “program voltage Vpgms”. In a case where the program operation PG in the first program mode is specified, the program operation is referred to as a “program operation PG1”. Furthermore, in a case where the first time of the program operation PG1 in the first program mode is specified, the program operation is referred to as “program operation PG1_1”. Similarly, in a case where the program operation PG in the second program mode is specified, the program operation is referred to as a “program operation PG2”. Furthermore, in a case where the first time of the program operation PG2 in the second program mode is specified, the program operation is referred to as “program operation PG2_1”. The same applies to the program operation PG of the second and subsequent program loops. In a case where the program verify operation PV in the first program mode is specified, the program verify operation is referred to as a “program verify operation PV1”. Further, in a case where a first time of the program verify operation PV1 in the first program mode is specified, the program verify operation is referred to as a “program verify operation PV1_1”. Similarly, in a case where the program verify operation PV in the second program mode is specified, the program verify operation is referred to as a “program verify operation PV2”. Further, in a case where the first time of the program verify operation PV2 in the second program mode is specified, the program verify operation is referred to as a “program verify operation PV2_1”. The same applies to the program verify operation PV of the second and subsequent program loops.

Next, a specific example of the first program mode will be described. In the program operation PG1_1, the row decoder 20 applies the voltage Vpgm1 to the selected word line WL as the program voltage Vpgmf of the first time of the program loop. Then, in the program verify operation PV1_1, the row decoder 20 applies a verify voltage Vvfy based on the target level (write target state) to the selected word line WL. For example, in the case of the program verify operation PV corresponding to the write operation of the “S1” state, the voltage V1 is set as the verify voltage Vvfy. The verify voltage Vvfy is based on the target level. Therefore, the verify voltage Vvfy is not stepped up based on the repetition of the program loop. In the example of FIG. 10, the verify voltage Vvfy having the same voltage value is applied to the selected word line WL in each program verify operation PV.

The row decoder 20 steps up the program voltage Vpgmf by a voltage dVpgm every time the program operation PG is repeated. The voltage dVpgm is a step-up voltage. Note that the voltage dVpgm may take a voltage value different for each program loop or operation mode. For example, in the program operation PG1_2, the row decoder 20 applies a voltage Vpgm2 (=Vpgm1+dVpgm) to the selected word line WL as the program voltage Vpgmf of a second time of the program loop. The voltage Vpgm2 is a voltage obtained by adding the voltage dVpgm to the voltage Vpgm1. In the program operation PG1_3, the row decoder 20 applies a voltage Vpgm3 (=Vpgm1+2dVpgm) to the selected word line WL as the program voltage Vpgmf of a third time of the program loop. The voltage Vpgm3 is a voltage obtained by adding the voltage dVpgm to the voltage Vpgm2. In the program operation PG1_4, the row decoder 20 applies a voltage Vpgm4 (=Vpgm1+3dVpgm) to the selected word line WL as the program voltage Vpgmf of a fourth time of the program loop. The voltage Vpgm4 is a voltage obtained by adding the voltage dVpgm to the voltage Vpgm3. In the program operation PG1_5, the row decoder 20 applies a voltage Vpgm5 (=Vpgm1+4dVpgm) to the selected word line WL as the program voltage Vpgmf of a fifth time of the program loop. The voltage Vpgm5 is a voltage obtained by adding the voltage dVpgm to the voltage Vpgm4. In the program operation PG1_6, the row decoder 20 applies a voltage Vpgm6 (=Vpgm1+5dVpgm) to the selected word line WL as the program voltage Vpgmf of a sixth time of the program loop. The voltage Vpgm6 is a voltage obtained by adding the voltage dVpgm to the voltage Vpgm5. In this manner, the row decoder 20 steps up the program voltage Vpgmf by the voltage dVpgm every time the program operation PG is repeated. In the example of FIG. 10, in the first program mode, the verification is passed in the sixth time of the program loop. In this case, in the program operation PG1_6, the voltage Vpgm6 (=Vpgm1+5dVpgm) is applied to the selected word line WL.

Next, a specific example of the second program mode will be described. The program voltage Vpgms (=Vpgm1+dV) in the program operation PG2_1 is set based on a result of the first program mode. For example, in order to prevent the threshold voltage of the memory cell transistor MC from being over-programmed, the program voltage Vpgmf in the program loop immediately before the program loop in which the verification is passed is set as the program voltage Vpgms of the program operation PG2_1. In the example of FIG. 10, in the first program mode, the memory cell transistor MC whose writing is fastest among the plurality of memory cell transistors MC in which the writing is performed at the same time passes the verification in the sixth time of the program loop. In this case, the voltage Vpgm5 (=Vpgm1+4dVpgm) of the program operation PG1_5 of the program loop immediately before (fifth time) is set as the program voltage Vpgms of the program operation PG2_1. That is, the voltage 4dVpgm is set as the shift voltage dV. Then, the program operation PG2_1 is executed using the voltage Vpgm5. In other words, in the second program mode, the write operation is executed from the fifth program loop of the first program mode. Similarly to the first program mode, the program voltage Vpgms is stepped up by the voltage dVpgm every time the program operation is repeated. For example, in the program operation PG2_2, the row decoder 20 applies a voltage Vpgm6 (=Vpgm1+5dVpgm) to the selected word line WL as the program voltage Vpgms of a second time of the program loop. As a result, for example, in the second program mode, the memory cell transistor MC whose writing is fastest passes the verification in the second time of the program loop. As a result, in the second program mode, the number of program loops can be reduced by four times.

Note that the shift voltage dV can be arbitrarily set. In the example of FIG. 10, the voltage Vpgm4 (=Vpgm1+3dVpgm) of the program operation PG1_4 of the program loop two times before (fourth time) may be set as the program voltage Vpgms of the program operation PG2_1. That is, the voltage 3dVpgm may be set as the shift voltage dV. In addition, an intermediate voltage between the voltage Vpgm4 (=Vpgm1+3dVpgm) of the program operation PG1_4 and the voltage Vpgm5 (=Vpgm1+4dVpgm) of the program operation PG1_5 may be set as the program voltage Vpgms of the program operation PG2_1. That is, a voltage higher than the voltage 3dVpgm and lower than the voltage 4dVpgm may be set as the shift voltage dV.

For example, the write operation of the string units SU0 and SU1 coupled to the selected word line WL0 of the array chip 3a is executed. The variation in the write characteristics between the string unit SU0 and the string unit SU1 is relatively small. In such a case, the first program mode is selected in the write operation of the string unit SU0. Then, in the write operation of the string unit SU1, the second program mode is selected.

### 1.3.2 Variation in Write Characteristics of Memory Cell Transistor

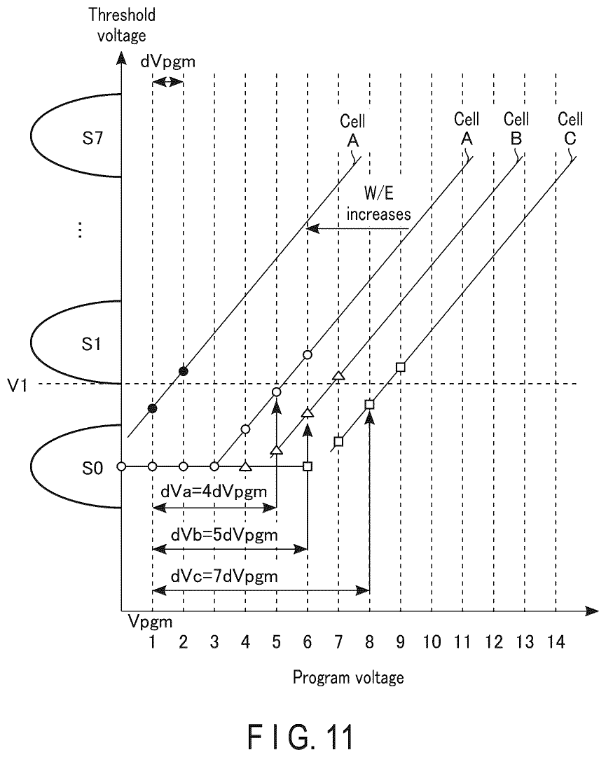

Next, the variation in the write characteristics of the memory cell transistor MC will be described with reference to FIG. 11. FIG. 11 is a graph illustrating a relationship between the threshold voltage of the memory cell transistor MC and the program voltage Vpgm. The example of FIG. 11 shows an increase in the threshold voltage of the memory cell transistor MC in the write operation corresponding to the “S1” state. In the example of FIG. 11, a cell A, a cell B, and a cell C indicate the memory cell transistors MC having different write characteristics, respectively. Similarly to the above, a focus is given on optimal write voltage adjustment without over-programming, and thus, these indicate the characteristics of the memory cell transistor MC whose writing is fastest among some of the string units SU. For example, the variation in the write characteristics is caused by a difference in the cell size of the memory cell transistor MC due to a difference in the stacking position of the word line WL, a difference in the interconnect length of the word line WL (interconnect resistance and RC time constant) from the memory cell transistor MC to the row decoder 20 for each array chip 3, and the like.

In the example of FIG. 11, a white circle of the cell A, a white triangle of the cell B, and a white square of the cell C indicate a state in which the number of cycles of the write operation and the erase operation (hereinafter, described as a “number of times of W/E”) is relatively small (for example, a state immediately after shipment). A black circle of the cell A indicates a state in which the number of times of W/E is relatively large (for example, a state close to the upper limit of the number of times of W/E).

First, the description will be given focusing on the cell A. As illustrated in FIG. 11, the threshold voltage of the memory cell transistor MC rises at a lower program voltage Vpgm as the number of times of W/E increases. Therefore, the voltage Vpgm1 is set to such a voltage value that over-programming does not occur in the program operation PG of the first time of the program loop even in a case where the number of times of W/E is close to the upper limit.

For example, in the case of the cell A (white circle), the threshold voltage rises up to the “S1” state by applying the voltage Vpgm6 to the selected word line WL. Therefore, in a case where the first program mode is selected, the program loop is executed six times. The shift voltage dV corresponding to the cell A is referred to as a shift voltage dVa. In a case where the second program mode is selected, for example, the voltage 4dVpgm is set as the shift voltage dVa. That is, in the program operation PG2_1, the voltage Vpgm5 (=Vpgm1+4dVpgm) is applied as the program voltage Vpgms. Accordingly, in a case where the second program mode is selected, the write operation is terminated by two times of the program loop.

For example, in the case of the cell B, the threshold voltage rises up to the “S1” state by applying the voltage Vpgm7 to the selected word line WL. Therefore, in a case where the first program mode is selected, the program loop is executed seven times. The shift voltage dV corresponding to the cell B is referred to as a shift voltage dVb. In a case where the second program mode is selected, for example, the voltage 5dVpgm is set as the shift voltage dVb. That is, in the program operation PG2_1, the voltage Vpgm6 (=Vpgm1+5dVpgm) is applied as the program voltage Vpgms. Accordingly, in a case where the second program mode is selected, the write operation is terminated by two times of the program loop.

For example, in the case of the cell C, the threshold voltage rises up to the “S1” state by applying the voltage Vpgm9 to the selected word line WL. Therefore, in a case where the first program mode is selected, the program loops is executed nine times. The shift voltage dV corresponding to the cell C is referred to as a shift voltage dVc. In a case where the second program mode is selected, for example, 7dVpgm is set as the shift voltage dVc. That is, in the program operation PG2_1, the voltage Vpgm8 (=Vpgm1+7dVpgm) is applied as the program voltage Vpgms. Accordingly, in a case where the second program mode is selected, the write operation is terminated by two times of the program loop.

That is, by setting a different shift voltage dV for each of pages of the groups of the memory cell transistors MC having different fastest write characteristics, that is, the string units SU, it is possible to reduce the variation in the number of program loops in a case where the second program mode is selected.

### 1.3.3 Voltage of Each Interconnect in Write Operation

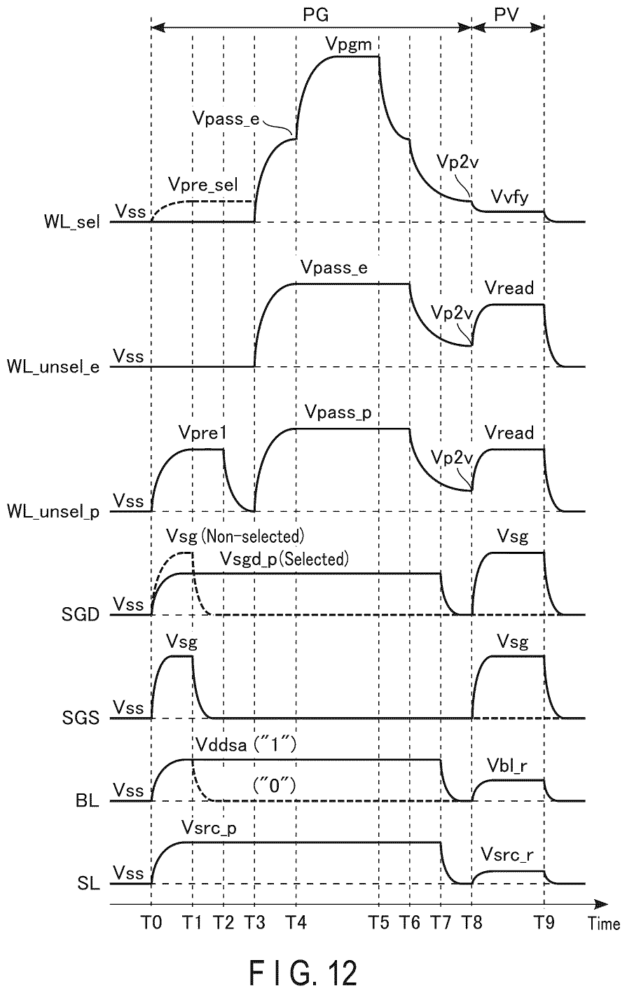

Next, the voltage of each interconnect in the write operation will be described with reference to FIG. 12. FIG. 12 is a timing chart illustrating the voltage of each interconnect in the write operation. The example of FIG. 12 shows one program loop. In the following description, the selected word line WL will be referred to as a “selected word line WL_sel”. In a case where the non-selected word line WL from which data has been erased is specified among the non-selected word lines WL, the non-selected word line WL will be denoted as a “non-selected word lines WL_unsel_e”. In a case where the non-selected word line WL in which data has been written is specified among the non-selected word lines WL, the non-selected word line WL will be denoted as a “non-selected word line WL_unsel_p”.

As illustrated in FIG. 12, first, the program operation PG at times T0 to T8 will be described.

In the program operation PG, a period from the time T0 to the time T3 is a precharge period of the channel of the selected memory cell transistor MC (hereinafter, referred to as a “selected memory cell transistor MC”).

At the time T0, precharge for inhibiting writing is performed on the channel of each NAND string NS in the selected block BLK. More specifically, the sense amplifier 30 applies a voltage Vddsa to the bit lines BL. The voltage Vddsa is a positive voltage higher than the voltage Vss. A voltage Vsrc_p is applied to the source lines SL (source lines SLa and SLb). The voltage Vsrc_p is a voltage for the purpose of precharging of the channel and improving cutoff characteristics of the selection transistor ST2. The voltage Vsrc_p is a positive voltage higher than the voltage Vss. Note that the voltage Vsrc_p may have the same voltage value as the voltage Vddsa. The row decoder 20 applies a voltage Vsgd_p to the select gate line SGD corresponding to the selected string unit SU. The voltage Vsgd_p is higher than the threshold voltage of the selection transistor ST1. The selection transistor ST1 is turned on. As a result, a voltage of the bit line BL equal to or higher than the voltage Vss is applied to the channel of the NAND string NS in the selected string unit SU. The row decoder 20 applies a voltage Vsg to the select gate line SGS and the select gate line SGD corresponding to the non-selected string unit SU. The voltage Vsg is higher than the voltage Vddsa. As a result, a higher voltage can be applied from the bit line BL or the source line SL to the channel of the NAND string NS in the non-selected string unit SU in a range of the voltage applied to the bit line BL or the source line SL. In addition, the row decoder 20 applies a voltage Vpre1 to the non-selected word line WL_unsel_p. The voltage Vpre1 is higher than the threshold voltage of the memory cell transistor MC that has been written. As a result, the memory cell transistor MC to which data has been written is turned on. The row decoder 20 applies the voltage Vss to the non-selected word line WL_unsel_e. The threshold voltage of the memory cell transistor MC from which data has been erased is lower than the voltage Vss. Therefore, the threshold voltage of the memory cell transistor MC from which data has been erased is turned on. The row decoder 20 applies the voltage Vss to the selected word line WL_sel. The selected memory cell transistor MC is turned on because the data has been erased. The row decoder 20 may apply a voltage Vpre_sel to the selected word line WL_sel. The voltage Vpre_sel is higher than the voltage Vss. By these operations, precharge is performed from the bit line BL or the source line SL to the channel of each NAND string NS in the selected block BLK.

At the time T1, the row decoder 20 applies the voltage Vss to the select gate line SGS and the select gate line SGD that is corresponding to the non-selected string unit SU. The selection transistor ST2 and the selection transistor ST1 that is corresponding to the non-selected string unit SU are turned off. As a result, the channel of each NAND string NS in the non-selected string unit SU is in a floating state.

In this state, the sense amplifier 30 applies the voltage Vss to the bit line BL corresponding to “0” data, that is, the bit line BL corresponding to the program-target selected memory cell transistor MC. As a result, the voltage Vss is applied to the channel corresponding to the program-target selected memory cell transistor MC in the selected string unit SU (the channel is discharged). On the other hand, the sense amplifier 30 continues to apply the voltage Vddsa to the bit line BL corresponding to “1” data, that is, the bit line BL corresponding to the program-inhibited selected memory cell transistor MC. Therefore, the selection transistor ST1 corresponding to the program-inhibited selected memory cell transistor MC is turned off. As a result, the channel corresponding to the program-inhibited selected memory cell transistor MC in the selected string unit SU is in a floating state. That is, each channel in the non-selected string unit SU and a channel corresponding to the program-inhibited selected memory cell transistor MC in the selected string unit SU are in a floating state.

At the time T2, the row decoder 20 applies the voltage Vss to the non-selected word line WL_unsel_p.

The times T3 to T7 are periods during which a write pulse is applied.

At the time T3, the row decoder 20 applies a voltage Vpass_e to the selected word line WL_sel and the non-selected word line WL_unsel_e. The voltage Vpass_e is a voltage applied to the memory cell transistor MC in the erase state. The voltage Vpass_e is a voltage that can be set regardless of the threshold voltage of the memory cell transistor MC in the write state. In addition, the row decoder 20 applies the voltage Vpass_p to the non-selected word line WL_unsel_p. The voltage Vpass_p is a voltage applied to the memory cell transistor MC in the write state. The voltage Vpass_p is a voltage that turns on the memory cell transistor MC regardless of the threshold voltage of the memory cell transistor MC. The voltage Vpass_p is higher than the voltage Vpre1. The voltage values of the voltages Vpass_e and Vpass_p may be different for each word line WL. For example, the row decoder 20 applies the voltage Vpass_p to each of the plurality of non-selected word lines WL_unsel_p.

Each channel in the non-selected string unit SU and each channel corresponding to the program-inhibited selected memory cell transistor MC in the selected string unit SU are in a floating state. The potentials of these channels rise due to coupling along with the rise of the potential of the word line WL (hereinafter, referred to as “channel boost”). Due to the channel boost, a potential difference between the word line WL and the channel is limited to a range in which writing (increase in threshold voltage) does not occur.

Unlike the example shown in FIG. 12, in the period from the time T2 to the time T4, the row decoder 20 may continuously apply the voltage Vpre1 without applying the voltage Vss to the non-selected word line WL_unsel_p.

At the time T4, the row decoder 20 applies a program voltage Vpgm to the selected word line WL_sel. The voltage Vpgm is a high voltage for injecting electrons into the charge storage layer of the program-target selected memory cell transistor MC. For example, in the program operation PG1_1 in the first program mode, the voltage Vpgm1 is set as the program voltage Vpgm. The program voltage Vpgm is a voltage higher than the voltage Vpass_e and the voltage Vpass_p. As a result, in the program-target selected memory cell transistor MC, the potential difference (Vpgm-Vss) between the selected word line WL_sel and the channel increases. As a result, electrons are injected into the charge storage layer, and the threshold voltage of the selected memory cell transistor MC is increased. On the other hand, in the program-inhibited selected memory cell transistor MC, the potential difference between the selected word line WL_sel and the channel is smaller than that in the program-target memory cell transistor MC due to the channel boost. As a result, electrons are hardly injected into the charge storage layer, and the threshold voltage of the memory cell transistor MC is maintained (the threshold voltage does not fluctuate to the extent that the write target state transitions to a higher distribution).

At the time T5, the row decoder 20 applies the voltage Vpass_e to the selected word line WL_sel. That is, the program voltage Vpgm is discharged.

During a period from the time T6 to the time T8, the row decoder 20 discharges the voltages applied to the selected word line WL_sel, the non-selected word line WL_unsel_e, and the non-selected word line WL_unsel_p. For example, the potentials of the selected word line WL_sel, the non-selected word line WL_unsel_e, and the non-selected word line WL_unsel_p decrease to a voltage Vp2v. The voltage Vp2v is higher than the voltage Vss.

At the time T7, the row decoder 20 applies the voltage Vss to the select gate lines SGD and SGS. In addition, the voltage Vss is applied to the source line SL. As a result, the program operation ends.

Next, the program verify operation PV at the times T8 to T9 will be described.

At the time T8, the row decoder 20 applies the verify voltage Vvfy to the selected word line WL_sel. The sequencer 53 determines whether the verification has been passed or failed based on the comparison result between the threshold voltage of the memory cell transistor MC and the verify voltage Vvfy. The row decoder 20 applies a voltage Vread to the non-selected word line WL_unsel_e and the non-selected word line WL_unsel_p. As a result, the non-selected memory cell transistor MC is turned on. The row decoder 20 applies the voltage Vsg to the select gate line SGS and the select gate line SGD corresponding to the selected string unit SU. The row decoder 20 applies the voltage Vss to the select gate line SGD corresponding to the non-selected string unit SU. As a result, in the selected string unit SU, the selection transistor ST1 is turned on. In the non-selected string unit SU, the selection transistor ST1 is turned off. Note that the row decoder 20 may apply the voltage Vss after temporarily applying a voltage higher than the voltage Vss to the select gate line SGD corresponding to the non-selected string unit SU immediately after the time T8. As a result, the selection transistor ST1 is temporarily turned on. By temporarily turning on the selection transistor ST1 of the non-selected string unit SU, the channel of the NAND string NS of the non-selected string unit SU is discharged.

The sense amplifier 30 applies a voltage Vbl_r to the bit line. The voltage Vbl_r is a positive voltage higher than the voltage Vss. A voltage Vsrc r is applied to the source line SL. The voltage Vsrc r is higher than the voltage Vss and lower than the voltage Vbl_r. During a period from the time T8 to the time T9, the sense amplifier 30 reads data of the selected memory cell transistor MC.

At the time T9, the row decoder 20 applies the voltage Vss to the selected word line WL_sel, the non-selected word line WL_unsel_e, the non-selected word line WL_unsel_p, and the select gate lines SGD and SGS. The sense amplifier 30 applies the voltage Vss to the bit line BL. A voltage Vss is applied to the source line SL. As a result, the program verify operation PV ends.

### 1.3.4 Command Sequence of Write Operation

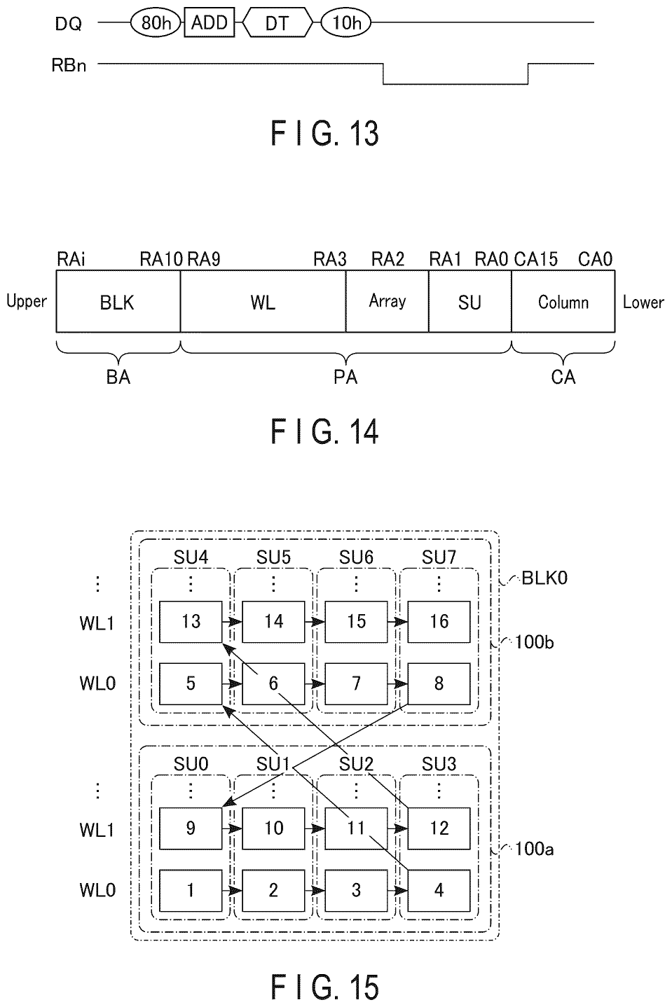

Next, an example of a command sequence of the write operation will be described with reference to FIG. 13. FIG. 13 is the command sequence of the write operation. The example of FIG. 13 illustrates the signal DQ and the signal RBn in order to simplify the description. The signals CEn, CLE, ALE, WEn, and REn are omitted. Hereinafter, in the signal DQ, the command is indicated by a rounded frame, the memory address is indicated by a square frame, and the data is indicated by a hexagonal frame.

As illustrated in FIG. 13, the memory controller 2 transmits a command set of the write operation to the semiconductor memory device 1. The command set of the write operation includes a command “80h”, the memory address ADD, the data DT, and a command “10h”.

First, the memory controller 2 transmits the command “80h” to the semiconductor memory device 1. The command “80h” is a command notifying that the write operation will be performed.

Next, the memory controller 2 transmits the memory address ADD, the data DT, and a command “10h” to the semiconductor memory device 1. The command “10h” is a command instructing execution of the write operation. The memory address ADD can be transmitted in a plurality of cycles based on the configuration of the memory cell array 100.

Upon reception of the command “10h”, the sequencer 53 sets the ready/busy signal RBn to the “L” level and executes the write operation.

Upon completion of the write operation, the sequencer 53 sets the ready/busy signal RBn to the “H” level.

### 1.3.5 Memory Address

Next, an example of the memory address ADD will be described with reference to FIG. 14. FIG. 14 is a configuration diagram of the memory address ADD.

As illustrated in FIG. 14, the memory address ADD includes the block address BA, the page address PA, and the column address CA. In the example of FIG. 14, the column address CA is set to a lower address side, and the block address BA is set to an upper address side.

The column address CA is, for example, an area indicated by a 16 bit binary number from an address CA0 to an address CA15. For example, the number of bits of the column address CA is arbitrarily set based on the number of bit lines BL (data length of one page data).

The page address PA is, for example, a region indicated by a 10 bit binary number from an address RA0 to an address RA9. The number of bits of the page address PA is arbitrarily set, for example, based on the configuration of the block BLK.

The block address BA is, for example, a region indicated by an address RA10 to an address RAi (i is an integer greater than 10). The number of bits of the block address BA is arbitrarily set, for example, based on the number of blocks BLK.

Next, details of the configuration of the page address PA will be described.

In the example of FIG. 14, the page address PA includes a string unit (SU) address, an array address, and a word line (WL) address from the lower address side. For example, an order of selection of the cell units CU in the write operation or the read operation is based on the order of the addresses of the page addresses PA.

The string unit address is address information used for selecting the string units SU, that is, the select gate lines SGD. For example, in a case where one array chip 3 includes four string unit SU, the string unit address is indicated by the address RA0 and the address RA1 of two bits. Note that the number of bits of the string unit address is arbitrarily set based on, for example, the number of string units SU included in one array chip 3.

The array address is address information used for selecting the array chip 3. For example, in a case where the semiconductor memory device 1 includes two array chips 3a and 3b, that is, in a case where the memory cell array 100 includes the memory cell arrays 100a and 100b, the array address is indicated by the address RA2 of one bit. The number of bits of the array address is arbitrarily set based on the number of the array chips 3, for example.

The word line address is address information used for selecting the word line WL. In a case where one block BLK includes 128 word lines WL, word line addresses are indicated by the addresses RA3 to RA9 of seven bits. The number of bits of the word line address is arbitrarily set based on, for example, the number of word lines WL included in one block BLK.

### 1.3.6 Writing Order of Data

Next, an example of the writing order of data will be described with reference to FIG. 15. FIG. 15 is a diagram illustrating the writing order of data based on the memory address ADD illustrated in FIG. 14. The example of FIG. 15 schematically illustrates a cross-sectional configuration of the string units SU in the block BLK0. One square in each string unit SU represents one cell unit CU corresponding to one word line WL. That is, one square corresponds to one write operation. The numbers in the squares in FIG. 15 indicate the writing order (selection order) of data in the cell units CU.

As shown in FIG. 15, for example, the block BLK0 includes eight string units SU0 to SU7. The string units SU0 to SU3 are provided in the memory cell array 100a (array chip 3a). The string units SU4 to SU7 are provided in the memory cell array 100b (array chip 3b).

For example, first, in a state where the word line WL0 and the array chip 3a (memory cell array 100a) are selected, the string unit address of the lower address is incremented. That is, the string units SU0 to SU3 of the memory cell array 100a are sequentially selected (write order “1” to “4”). Next, the array address of the upper address is incremented, and the array chip 3b (memory cell array 100b) is selected. In this state, the string unit address of the lower address is incremented. That is, the string units SU4 to SU7 of the memory cell array 100b are sequentially selected (write order “5” to “7”). Next, the word line address located above the array address is incremented. As a result, the word line WL1 is selected. As in the case of the word line WL0, the string units SU0 to SU3 (write order “9” to “12”) of the memory cell array 100a and the string units SU4 to SU7 (write order “13” to “16”) of the memory cell array 100b are sequentially selected. Thereafter, the word line WL, the array chip 3, and the string unit SU are similarly selected.

### 1.3.7 Specific Example of Operation Mode Selection

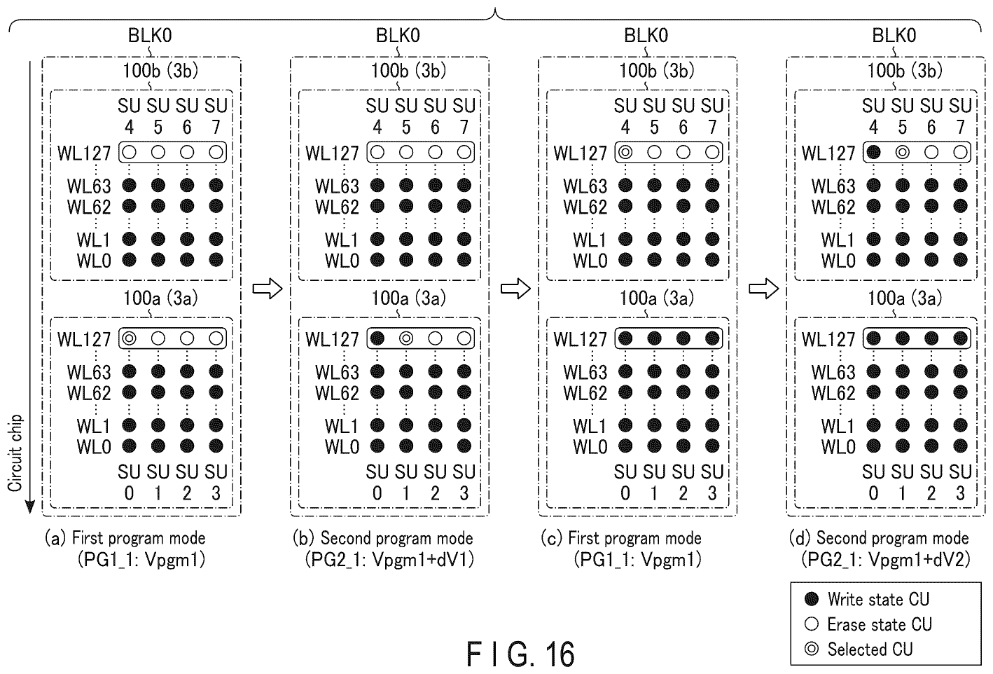

Next, a specific example of operation mode selection will be described with reference to FIG. 16. FIG. 16 is a diagram illustrating an example of selection of the operation mode in the block BLK0. The example of FIG. 16 illustrates a case where the write operations of the string units SU0 to SU7 corresponding to the selected word line WL127 are sequentially executed. In the example of FIG. 16, one circle indicates one cell unit CU. A black circle indicates a state in which data is written in the cell unit CU (a state in which valid data is stored). A white circle indicates a state in which data in the cell unit CU has been erased (a state in which valid data is not stored). A double circle indicates the selected cell unit CU.

As shown in FIG. 16, for example, the block BLK0 includes eight string units SU0 to SU7. The memory cell array 100a (array chip 3a) includes the string units SU0 to SU3. The memory cell array 100b (array chip 3b) includes string units SU4 to SU7. Therefore, the write operation of the string units SU0 to SU7 corresponding to the word line WL127 is started from the string unit SU0 of the array chip 3a close to the circuit chip 4. The memory cell arrays 100a and 100b share the word lines WL0 to WL127. More specifically, in each of the memory cell arrays 100a and 100b, 128 word lines WL0 to WL127 are provided from the bit line BL side toward the source line SL side. That is, the word lines WL0 to WL127 of the array chips 3 are sequentially arranged in a direction away from the circuit chip 4. Therefore, in a case where the word lines WL0 to WL127 are sequentially selected, the word lines WL are sequentially selected from the word line WL on the side closer to the circuit chip 4 in each array chip 3.

The plurality of memory pillars MP in the same array chip 3 are collectively provided. Therefore, the variation in the write characteristics of the plurality of string units SU in the same array chip 3 is relatively small. That is, the string units SU0 to SU3 of the array chip 3a have relatively small variations in write characteristics. Similarly, the string units SU4 to SU7 of the array chip 3b have relatively small variations in write characteristics. On the other hand, the array chip 3a and the array chip 3b are manufactured separately. Therefore, the variation in the write characteristics of the string units SU in the plurality of array chips 3 can be larger than the variation in the write characteristics of the plurality of string units SU in the same array chip 3. Therefore, in the present embodiment, in a case where the write operation of the plurality of string units SU (cell units CU) coupled to one selected word line WL is sequentially executed, the first program mode is selected in the write operation of the string unit SU of each array chip 3 that has been first selected. Then, in the write operation of another string unit SU, the second program mode is selected. In other words, in a case where the selected string unit SU of the write operation is the first string unit SU in the array chip 3, the first program mode is selected. Then, in a case where the selected string unit SU is not the first string unit SU in the array chip 3, the second program mode is selected. The shift voltage dV in the second program mode is set for each of the array chips 3. That is, in each array chip 3, the shift voltage dV is set based on a result of the write operation of the first string unit SU in which the first program mode is selected.

FIG. 16(a) illustrates a state in which the string unit SU0 of the array chip 3a is selected. The string unit SU0 is the first string unit SU corresponding to the selected word line WL127 in the array chip 3a. Therefore, in the write operation of the string unit SU0, the first program mode is selected. In this case, in the program operation PG1_1 of the first time of the program loop, the voltage Vpgm1 is applied to the selected word line WL127.

FIG. 16(b) illustrates a state in which the string unit SU1 of the array chip 3a is selected. The string unit SU1 is not the first string unit SU corresponding to the selected word line WL127 in the array chip 3a. Therefore, in the write operation of the string unit SU1, the second program mode is selected. For example, in the program operation PG2_1 of the first time of the program loop, the voltage (Vpgm1+dV1) is applied to the selected word line WL127. The shift voltage dV1 is set based on a result of the write operation of the string unit SU0. The same applies to the string units SU2 and SU3.

FIG. 16(c) illustrates a state in which the string unit SU4 of the array chip 3b is selected. The string unit SU4 is the first string unit SU corresponding to the selected word line WL127 in the array chip 3b. Therefore, in the write operation of the string unit SU4, the first program mode is selected. Therefore, in the program operation PG1_1 of the first time of the program loop, the voltage Vpgm1 is applied to the selected word line WL127.

FIG. 16(d) illustrates a state in which the string unit SU5 of the array chip 3b is selected. The string unit SU5 is not the first string unit SU corresponding to the selected word line WL127 in the array chip 3b. Therefore, in the write operation of the string unit SU5, the second program mode is selected. For example, in the program operation PG2_1 of the first time of the program loop, the voltage (Vpgm1+dV2) is applied to the selected word line WL127. The shift voltage dV2 is set based on the result of the write operation of the string unit SU4. The shift voltage dV2 may be the same as or different from the shift voltage dV1. The same applies to the string units SU6 and SU7.

### 1.3.8 Flow of Write Operation

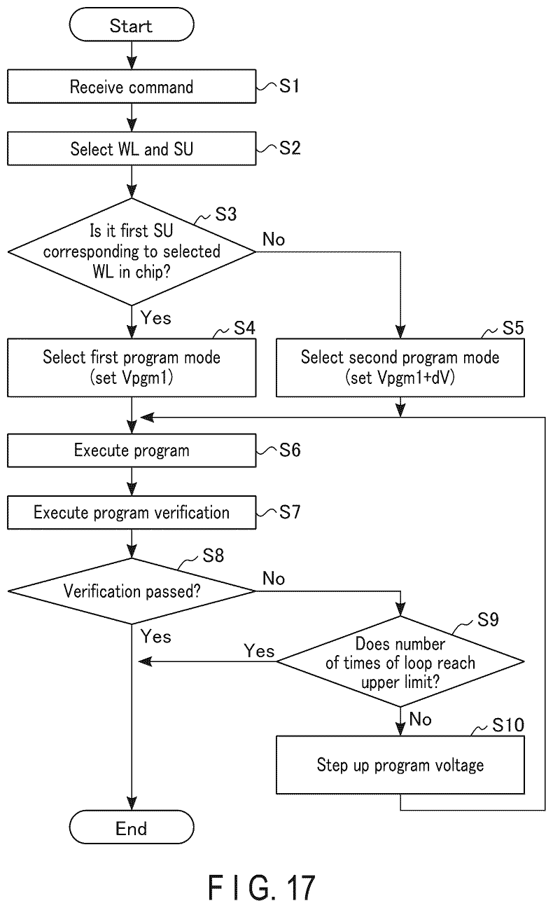

Next, an example of a flow of the write operation will be described with reference to FIG. 17. FIG. 17 is a flowchart of the write operation.

As illustrated in FIG. 17, the sequencer 53 receives the command set of the write operation from the memory controller 2 (S1).

The sequencer 53 selects the block BLK, the word line WL, the array chip 3, and the string unit SU based on the memory address ADD (S2).

The sequencer 53 checks whether the selected string unit SU is the first string unit SU corresponding to the selected word line WL in the array chip 3 (S3). In other words, the sequencer 53 checks whether the write operation to be executed is the first write operation corresponding to the selected word line WL in the array chip 3. More specifically, for example, if the selected string unit SU is the string unit SU0 or SU4, the sequencer 53 determines that it is the first string unit SU. On the other hand, for example, if the selected string unit SU is one of the string units SU1 to SU3 and SU5 to SU7, the sequencer 53 determines that it is not the first string unit SU.

In a case where the selected string unit SU is the first string unit SU (S3_Yes), the sequencer 53 selects the first program mode (S4). Then, the sequencer 53 sets the voltage Vpgm1 as the program voltage Vpgmf in the program operation PG1_1 of the first time of the program loop.

On the other hand, in a case where the selected string unit SU is not the first string unit SU (S3_No), the sequencer 53 selects the second program mode (S5). Then, the sequencer 53 sets the voltage (Vpgm1+dV) as the program voltage Vpgms in the program operation PG2_1 of the first time of the program loop. For example, the sequencer 53 stores the result of the write operation of the first string unit SU of the array chip 3, that is, the number of times of program loop in the first program mode. Then, the sequencer 53 sets the shift voltage dV based on the result of the write operation of the first string unit SU of the array chip 3.

The sequencer 53 executes the program operation PG based on the set program voltage Vpgm (S6).

Next, the sequencer 53 executes the program verify operation PV (S7).

In a case where the verification is failed (S8_No), the sequencer 53 checks whether the number of times of program loop has reached a preset upper limit number (S9).

In a case where the number of times of program loop reaches the upper limit (S9_Yes), the sequencer 53 ends the write operation. The semiconductor memory device 1 has a status register that stores a status for the write operation and the erase operation. As described above, in a case where the verification fails with a predetermined maximum number of loops, information on the failure is held in the status register.

In a case where the number of times of program loop has not reached the upper limit (S9_No), the sequencer 53 steps up the program voltage Vpgm (S10). Next, the sequencer 53 proceeds to S6 and executes the program operation PG of the next time of the program loop.

In a case where the verification is passed (S8_Yes), the sequencer 53 ends the write operation. In a case where the write oeration is normally ended, pass information is stored in the status register. The memory controller can check this status by performing status reading.

### 1.4 Effects According to Present Embodiment

With the configuration according to the present embodiment, the processing capability of the semiconductor memory device 1 can be improved. This effects will be described in detail.

In the write operation, the threshold voltage of the memory cell transistor MC rises to the write target state by repeating the program loop. At this time, the program voltage in the first time of the program operation is set to a relatively low voltage so that over-programming does not occur. However, in a case where the program voltage in the first time of the program operation is set low, the number of times of program loop tends to increase. That is, the processing time of the write operation tends to increase.

On the other hand, with the configuration according to the present embodiment, in a case where the write operation is executed, one of the first program mode and the second program mode can be selected. In the first program mode, the voltage Vpgm1 can be set as the program voltage Vpgmf of the first time of the program operation PG1_1. In the second program mode, the voltage (Vpgm1+dV) can be set as the program voltage Vpgms of the first time of the program operation PG2_1. The shift voltage dV is set based on the result of the write operation in which the first program mode is selected. The voltage (Vpgm1+dV) is higher than the voltage Vpgm1. That is, in the second program mode, the program loop can be started at a higher program voltage than in the first program mode. As a result, in a case where the second program mode is selected, the number of times of program loop can be reduced as compared with the first program mode. That is, the processing time of the write operation can be reduced. Therefore, the processing capability of the semiconductor memory device 1 can be improved.

Furthermore, with the configuration according to the present embodiment, the word lines WL can be shared by the plurality of array chips 3 stacked above the circuit chip 4. As a result, an increase in the circuit scale of the row decoder 20 can be suppressed. Therefore, it is possible to suppress an increase in an area of the chip of the semiconductor memory device 1.

Furthermore, with the configuration according to the present embodiment, in a case where the write operation of the plurality of string units SU coupled to one selected word line WL is sequentially executed, the first program mode is applied to the write operation of the string unit SU of each array chip 3 that has been first selected. Then, the second program mode can be applied to the write operation of another string unit SU. Therefore, even in a case where the variation in the write characteristics among the plurality of array chips 3 is relatively large, the optimum shift voltage dV can be set for each of the array chips 3. As a result, the occurrence of over-programming can be suppressed, and the reliability of the write operation can be improved. Therefore, the reliability of the semiconductor memory device 1 can be improved. Furthermore, since the optimum shift voltage dV can be set for each array chip 3, an increase in the number of times of program loop can be suppressed. That is, an increase in the processing time of the write operation can be suppressed. Therefore, the processing capability of the semiconductor memory device 1 can be improved.

### 1.5 Modifications

Next, two modifications of the first embodiment will be described. Hereinafter, differences from the first embodiment will be mainly described.

### 1.5.1 First Modification

First, a first modification of the first embodiment will be described. In the first modification, a case where the write operation is executed sequentially from the word line WL (memory cell transistor MC) on the source line SL side will be described.

### 1.5.1.1 Circuit Configuration of Memory Cell Array

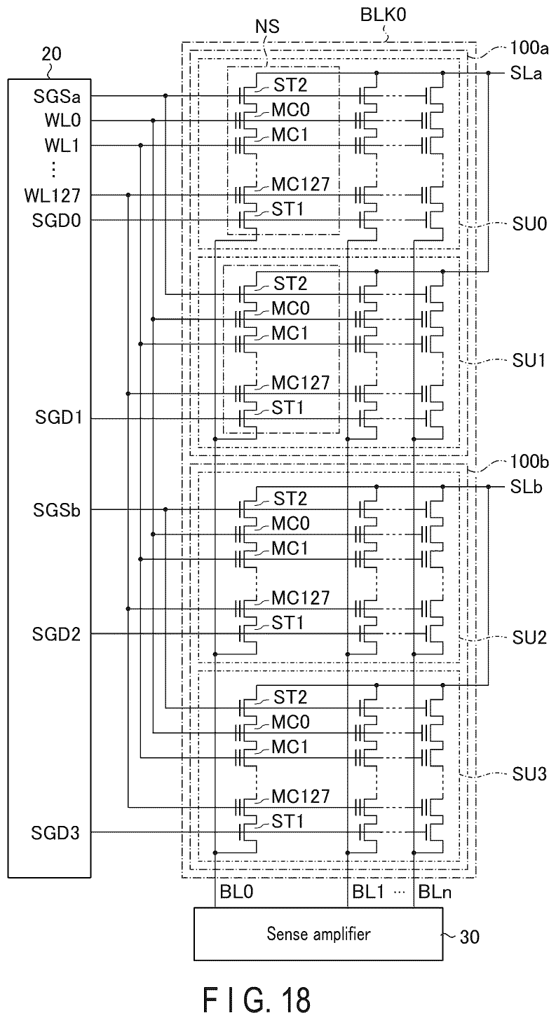

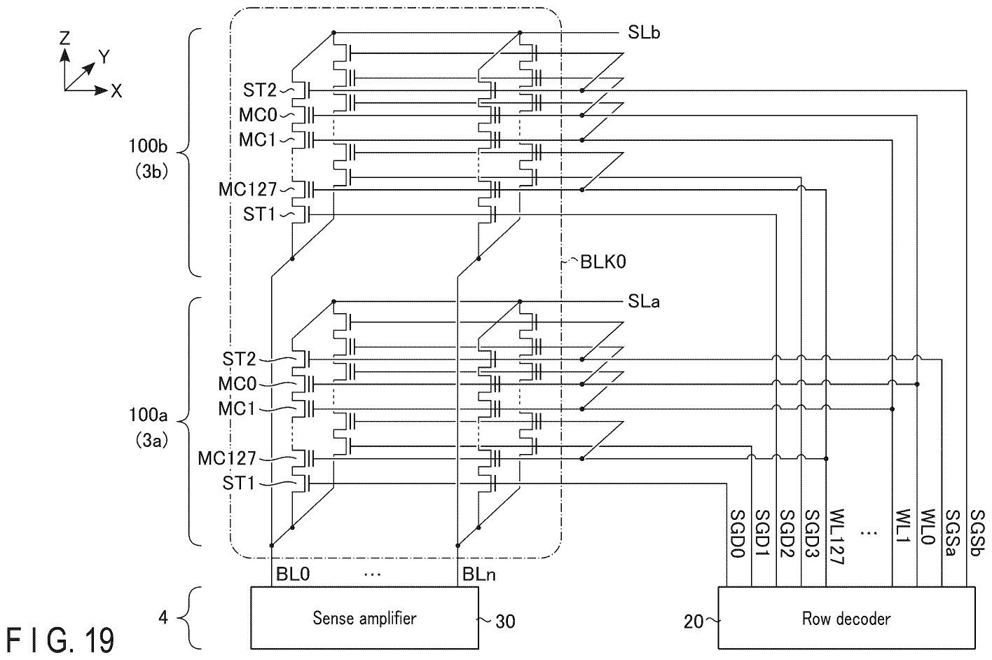

First, an example of a circuit configuration of the memory cell array 100 will be described with reference to FIGS. 18 and 19. FIG. 18 is a plan view illustrating the circuit configuration of the memory cell array 100. FIG. 19 is a perspective view illustrating the circuit configuration of the memory cell array 100. Note that the example of FIGS. 18 and 19 illustrate a circuit configuration of the block BLK0, and the same applies to the other blocks BLK.

As illustrated in FIGS. 18 and 19, in this example, the current paths of the selection transistor ST2, the memory cell transistors MC0 to MC127, and the selection transistor ST1 are coupled in series in this order. That is, the selection transistor ST2, the memory cell transistors MC0 to MC127, and the selection transistor ST1 are sequentially coupled from the source lines SL toward the bit lines BL. In other words, the word lines WL0 to WL127 are arranged in order from the source line SL side toward the bit line BL side. Other configurations are similar to those in FIGS. 2 and 3 of the first embodiment.

### 1.5.1.2 Specific Example of Operation Mode Selection

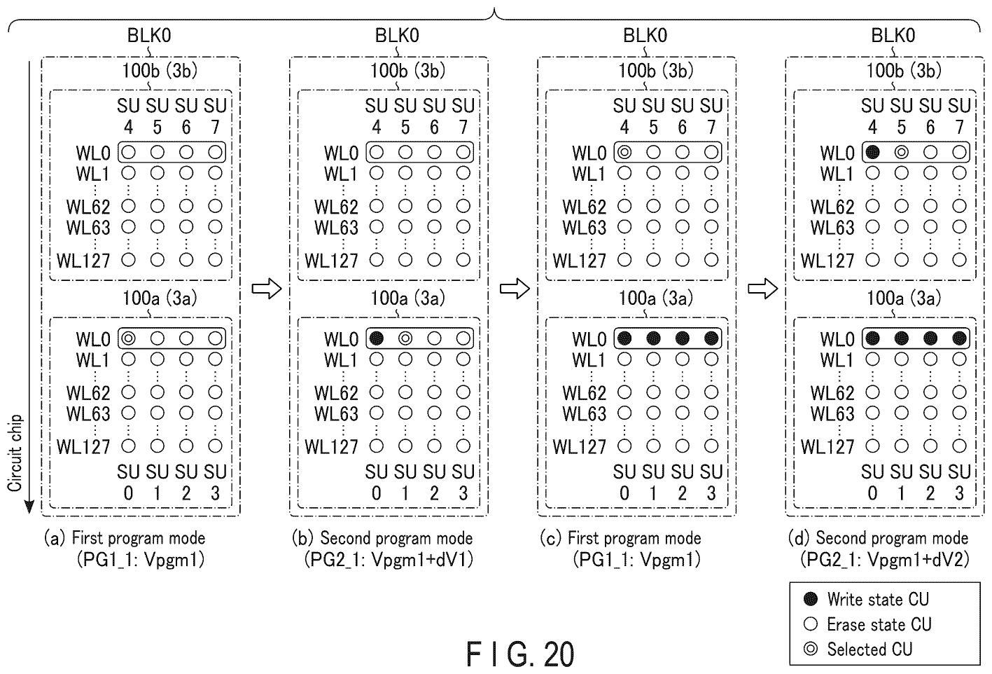

Next, a specific example of operation mode selection will be described with reference to FIG. 20. FIG. 20 is a diagram illustrating an example of the selection of the operation mode in the block BLK0. The example of FIG. 20 illustrates a case where the write operations of the string units SU0 to SU7 corresponding to the selected word line WL0 are sequentially executed.

In this example, as in the first embodiment, in a case where the selected string unit SU of the write operation is the first string unit SU in the array chip 3, the first program mode is selected. Then, in a case where the selected string unit SU is not the first string unit SU in the array chip 3, the second program mode is selected.

As shown in FIG. 20, in each of the memory cell arrays 100a and 100b, 128 word lines WL0 to WL127 are provided from the source line SL side toward the bit line BL side. That is, the word lines WL0 to WL127 are sequentially arranged toward the circuit chip 4. In other words, the word lines WL0 to WL127 of the array chips 3 are sequentially arranged in order toward the circuit chip 4. Therefore, in a case where the word lines WL0 to WL127 are sequentially selected, the word lines are sequentially selected from the word line WL on the side distant from the circuit chip 4 in each array chip 3.

FIG. 20(a) illustrates a state in which the string unit SU0 of the array chip 3a is selected. Similarly to the description of FIG. 16(a), the first program mode is selected in the write operation of the string unit SU0. Therefore, in the program operation PG1_1 of the first time of the program loop, the voltage Vpgm1 is applied to the selected word line WL0.

FIG. 20(b) illustrates a state in which the string unit SU1 of the array chip 3a is selected. Similarly to the description of FIG. 16(b), the second program mode is selected in the write operation of the string unit SU1. For example, in the program operation PG2_1 of the first time of the program loop, the voltage (Vpgm1+dV1) is applied to the selected word line WL0. The same applies to the string units SU2 and SU3.

FIG. 20(c) illustrates a state in which the string unit SU4 of the array chip 3b is selected. Similarly to the description of FIG. 16(c), the first program mode is selected in the write operation of the string unit SU4. Therefore, in the program operation PG1_1 of the first time of the program loop, the voltage Vpgm1 is applied to the selected word line WL0.

FIG. 20(d) illustrates a state in which the string unit SU5 of the array chip 3b is selected. Similarly to the description of FIG. 16(d), the second program mode is selected in the write operation of the string unit SU5. For example, in the program operation PG2_1 of the first time of the program loop, the voltage (Vpgm1+dV2) is applied to the selected word line WL0. The same applies to the string units SU6 and SU7.

### 1.5.2 Second Modification

Next, a second modification of the first embodiment will be described. In the second modification, a case where the arrangement of the array chips 3a and 3b is different from that of the first embodiment will be described.

### 1.5.2.1 Arrangement of Chips

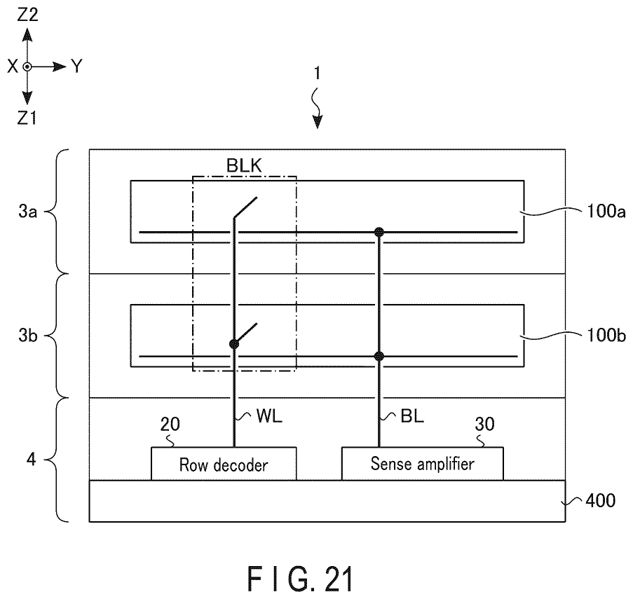

First, an example of arrangement of each chip will be described with reference to FIG. 21. FIG. 21 is a cross-sectional view illustrating the arrangement of the array chips 3a and 3b and the circuit chip 4. In the example of FIG. 21, one word line WL and one bit line BL are illustrated in order to simplify the description. The select gate lines SGD and SGS and the source lines SL are omitted.

As illustrated in FIG. 21, the array chip 3b is bonded onto the circuit chip 4 in the Z2 direction. Then, the array chip 3a is bonded onto the array chip 3b. In other words, the circuit chip 4 is bonded to a surface of the array chip 3b facing the Z1 direction. Then, the array chip 3a is bonded to a surface of the array chip 3b facing the Z2 direction. That is, the circuit chip 4, the array chip 3b, and the array chip 3a are sequentially stacked in the Z2 direction. Other configurations are similar to those in FIG. 5 of the first embodiment.

### 1.5.2.2 Circuit Configuration of Memory Cell Array

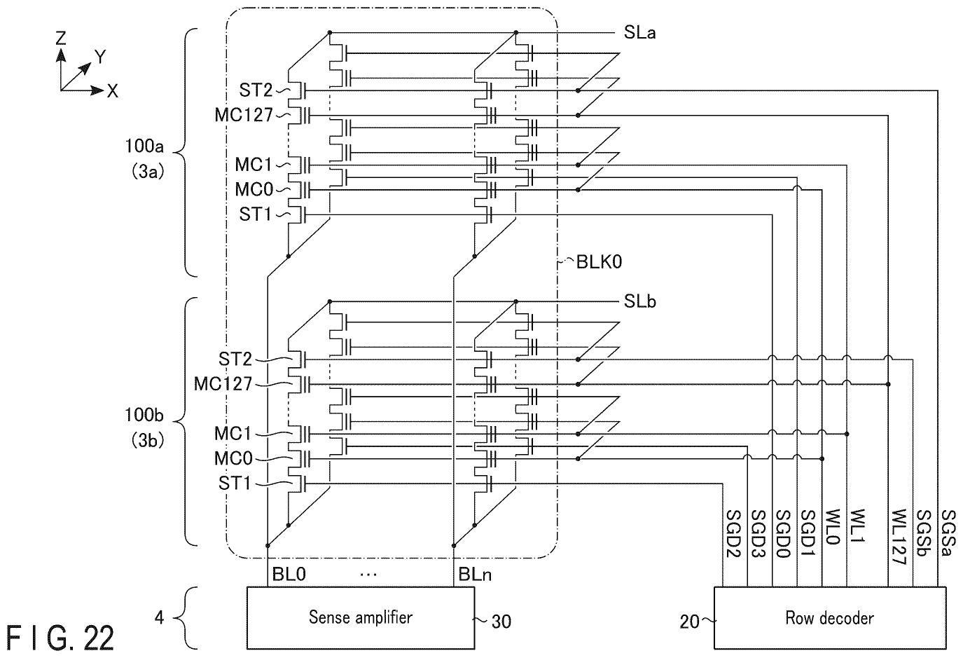

Next, an example of a circuit configuration of the memory cell array 100 will be described with reference to FIG. 22. FIG. 22 is a perspective view illustrating the circuit configuration of the memory cell array 100. Note that the example of FIG. 22 illustrates the circuit configuration of the block BLK0, and the same applies to the other blocks BLK.

As illustrated in FIG. 22, an array region (string units SU0 and SU1) of the block BLK0 of the memory cell array 100a is arranged above the array region (string units SU2 and SU3) of the block BLK0 of the memory cell array 100b. In other words, the array region of the block BLK0 of the array chip 3a and the array region of the block BLK0 of the array chip 3b are arranged side by side in the Z direction. That is, the NAND strings NS of the memory cell array 100b and the NAND strings NS of the memory cell array 100a arranged above the NAND strings NS of the memory cell array 100b are included in the same block BLK. Other configurations are similar to those in FIG. 3 of the first embodiment.

### 1.5.2.3 Specific Example of Operation Mode Selection

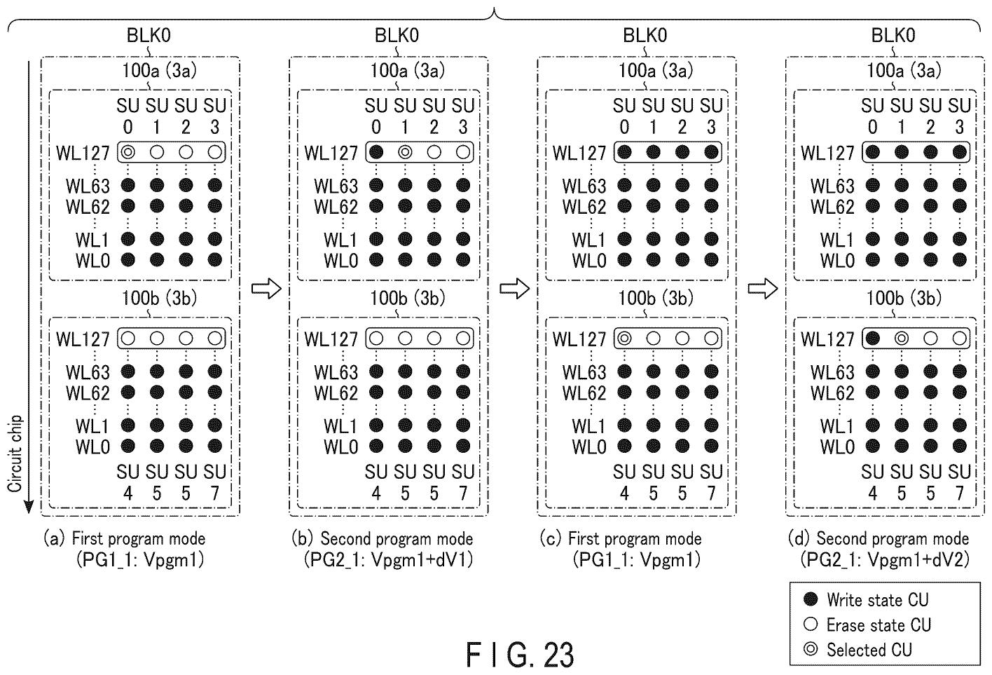

Next, a specific example of operation mode selection will be described with reference to FIG. 23. FIG. 23 is a diagram illustrating an example of the selection of the operation mode in the block BLK0. The example of FIG. 23 illustrates a case where the write operations of the string units SU0 to SU7 corresponding to the selected word line WL127 are sequentially executed.

In this example, as in the first embodiment, in a case where the selected string unit SU of the write operation is the first string unit SU in the array chip 3, the first program mode is selected. Then, in a case where the selected string unit SU is not the first string unit SU in the array chip 3, the second program mode is selected.

As illustrated in FIG. 23, the array chip 3b (memory cell array 100b) is arranged on the side closer to the circuit chip 4, and the array chip 3a (memory cell array 100a) is arranged on the far side. The configurations in the memory cell arrays 100a and 100b are similar to those in FIG. 16 of the first embodiment. In this example, the string unit SU0 on the array chip 3a far from the circuit chip 4 is first selected.

FIG. 23(a) illustrates a state in which the string unit SU0 of the array chip 3a is selected. Similarly to the description of FIG. 16(a), the first program mode is selected in the write operation of the string unit SU0. Therefore, in the program operation PG1_1 of the first time of the program loop, the voltage Vpgm1 is applied to the selected word line WL127.

FIG. 23(b) illustrates a state in which the string unit SU1 of the array chip 3a is selected. Similarly to the description of FIG. 16(b), the second program mode is selected in the write operation of the string unit SU1. For example, in the program operation PG2_1 of the first time of the program loop, the voltage (Vpgm1+dV1) is applied to the selected word line WL127. The same applies to the string units SU2 and SU3.

FIG. 23(c) illustrates a state in which the string unit SU4 of the array chip 3b is selected. Similarly to the description of FIG. 16(c), the first program mode is selected in the write operation of the string unit SU4. Therefore, in the program operation PG1_1 of the first time of the program loop, the voltage Vpgm1 is applied to the selected word line WL127.

FIG. 23(d) illustrates a state in which the string unit SU5 of the array chip 3b is selected. Similarly to the description of FIG. 16(d), the second program mode is selected in the write operation of the string unit SU5. For example, in the program operation PG2_1 of the first time of the program loop, the voltage (Vpgm1+dV2) is applied to the selected word line WL127. The same applies to the string units SU6 and SU7.

### 1.5.3 Effects According to Modifications of First Embodiment

With the configurations according to the first modification and the second modification of the first embodiment, the same effects as those of the first embodiment can be obtained. Note that the first modification and the second modification may be combined.

### 2. Second Embodiment

Next, a second embodiment will be described. In the second embodiment, a method of selecting the operation mode different from that of the first embodiment will be described. Hereinafter, differences from the first embodiment will be mainly described.

### 2.1 Specific Example of Operation Mode Selection

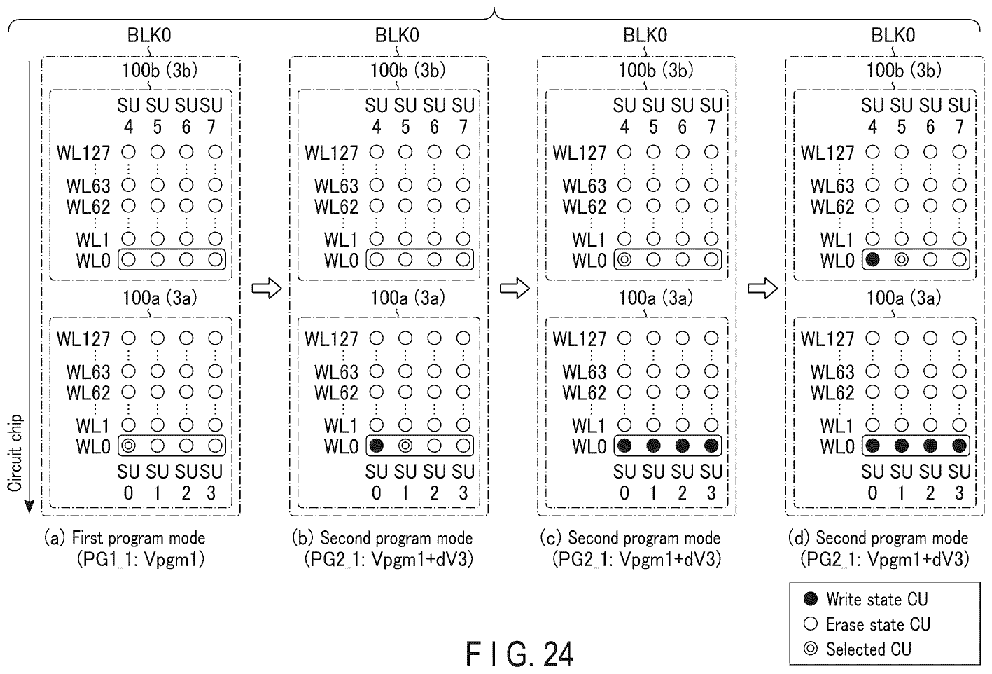

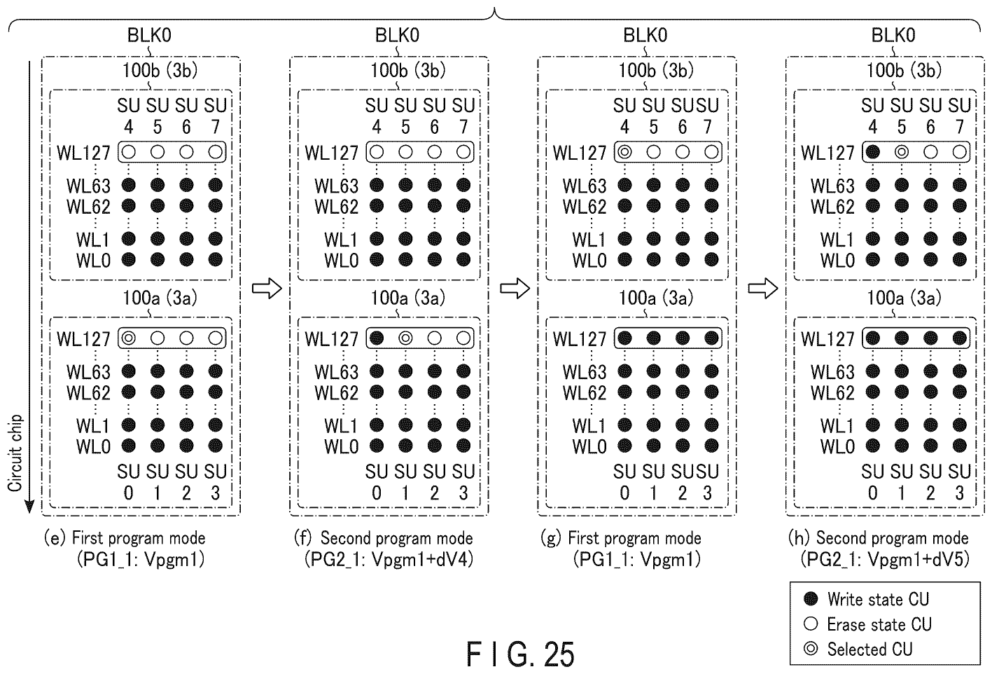

First, a specific example of operation mode selection will be described with reference to FIGS. 24 and 25. FIGS. 24 and 25 are diagrams illustrating an example of the selection of the operation mode in the block BLK0. The example of FIG. 24 illustrates a case where the word line WL0 is selected. The example of FIG. 25 illustrates a case where the word line WL127 is selected.

As illustrated in FIGS. 24 and 25, the configuration of the block BLK0 is similar to that in FIG. 16 of the first embodiment.

In the present embodiment, the method of selecting the operation mode of the write operation is different depending on the word line WL. The method for selecting the operation mode includes a first selection method and a second selection method.

For example, a magnitude of the variation in the shape (write characteristic) of the memory cell transistors MC of the plurality of array chips 3 varies depending on a position of the word line WL with respect to the memory pillar MP. Either the first selection method or the second selection method is applied based on the position of the word line WL, that is, the magnitude of the variation in the write characteristics in the plurality of array chips 3.

The first selection method is applied to a case where the variation in write characteristics is relatively small. More specifically, for example, in a case where the selected word line WL of the write operation is the word line WL arranged on the bit line BL side, the first selection method is applied. In the first selection method, the first program mode is selected in a case where the selected string unit SU of the write operation is the first string unit SU of the first array chip 3 corresponding to the selected word line WL. Then, in a case where the selected string unit SU is another string unit SU, the second program mode is selected. Therefore, in a case where the array chip 3 (hereinafter, referred to as a “selected array chip”) including the selected string unit SU is the second or subsequent selected array chip 3, the first program mode is not selected. In other words, in a case where the selected string unit SU of the write operation is the string unit SU0, the first program mode is selected. Then, in a case where the selected string unit SU is another string unit SU, the second program mode is selected. The shift voltage dV in the second program mode is set to the same value regardless of the array chip 3.

The second selection method is applied to a case where the variation in write characteristics is relatively large. More specifically, for example, in a case where the selected word line WL of the write operation is the word line WL arranged on the source line SL side, the second selection method is applied. In the second selection method, as in the first embodiment, in a case where the selected string unit SU of the write operation is the first string unit SU in the array chip 3, the first program mode is selected. Then, in a case where the selected string unit SU is not the first string unit SU in the array chip 3, the second program mode is selected.

The allocation of the selection method for the operation mode in each word line WL can be arbitrarily set. For example, the lower limit number of the word line WL to which the second selection method is applied is m (m is an integer of 1 or more). In a case where the selected word line WL is any of the word lines WL0 to WL(m−1), the first selection method may be applied, and in a case where the selected word line WL is any of the word lines WLm to WL127, the second selection method may be applied. In addition, the method of selecting the applied operation mode may be different for each word line WL.

First, a specific example of the first selection method will be described with reference to FIG. 24. In the present example, a case where the word line WL0 (that is, the memory cell transistor MC0) is selected as the selected word line WL on the bit line BL side will be described. That is, the write operation corresponding to the selected word line WL0 will be described. In a case where the selected word line WL is the word line WL0, the first selection method is applied.

FIG. 24(a) illustrates a state in which the string unit SU0 of the array chip 3a is selected. The string unit SU0 is the first string unit SU of the first array chip 3 corresponding to the selected word line WL0. Therefore, in the write operation of the string unit SU0, the first program mode is selected. For example, in the program operation PG1_1 of the first time of the program loop, the voltage Vpgm1 is applied to the selected word line WL0.

FIG. 24(b) illustrates a state in which the string unit SU1 of the array chip 3a is selected. The string unit SU1 is not the first string unit SU (that is, the string unit SU0) of the first array chip 3 corresponding to the selected word line WL0. Therefore, in the write operation of the string unit SU1, the second program mode is selected. For example, in the program operation PG2_1 of the first time of the program loop, the voltage (Vpgm1+dV3) is applied to the selected word line WL0. The shift voltage dV3 is set based on the result of the write operation of the string unit SU0. The same applies to the string units SU2 and SU3.

FIG. 24(c) illustrates a state in which the string unit SU4 of the array chip 3b is selected. The string unit SU4 is not the first string unit SU (that is, the string unit SU0) corresponding to the selected word line WL0. Therefore, in the write operation of the string unit SU4, the second program mode is selected. Similarly to the string units SU1 to SU3 (string units SU in which the second program mode is selected in the array chip 3a), in the program operation PG2_1 of the first time of the program loop, the voltage (Vpgm1+dV3) is applied to the selected word line WL0.

FIG. 24(d) illustrates a state in which the string unit SU5 of the array chip 3b is selected. Similarly to the string unit SU4, the second program mode is selected in the write operation of the string unit SU5. For example, in the program operation PG2_1 of the first time of the program loop, the voltage (Vpgm1+dV3) is applied to the selected word line WL0. The same applies to the string units SU6 and SU7.

Next, a specific example of the second selection method will be described with reference to FIG. 25. In the present example, a case where the word line WL127 (that is, the memory cell transistor MC127) is selected as the selected word line WL on the source line SL side will be described. That is, the write operation corresponding to the selected word line WL127 (memory cell transistor MC127) will be described. In a case where the selected word line WL is the word line WL127, the second selection method is applied.

FIG. 25(e) illustrates a state in which the string unit SU0 of the array chip 3a is selected. The string unit SU0 is the first string unit SU corresponding to the selected word line WL127 in the array chip 3a. Therefore, in the write operation of the string unit SU0, the first program mode is selected. Therefore, in the program operation PG1_1 of the first time of the program loop, the voltage Vpgm1 is applied to the selected word line WL127.

FIG. 25(f) illustrates a state in which the string unit SU1 of the array chip 3a is selected. The string unit SU1 is not the first string unit SU corresponding to the selected word line WL127 in the array chip 3a. Therefore, in the write operation of the string unit SU1, the second program mode is selected. For example, in the program operation PG2_1 of the first time of the program loop, the voltage (Vpgm1+dV4) is applied to the selected word line WL127. The shift voltage dV4 is set based on the result of the write operation of the string unit SU0. The same applies to the string units SU2 and SU3.

FIG. 25(g) illustrates a state in which the string unit SU4 of the array chip 3b is selected. The string unit SU4 is the first string unit SU corresponding to the selected word line WL127 in the array chip 3b. Therefore, in the write operation of the string unit SU4, the first program mode is selected. Therefore, in the program operation PG1_1 of the first time of the program loop, the voltage Vpgm1 is applied to the selected word line WL127.

FIG. 25(h) illustrates a state in which the string unit SU5 of the array chip 3b is selected. The string unit SU5 is not the first string unit SU corresponding to the selected word line WL127 in the array chip 3b. Therefore, in the write operation of the string unit SU5, the second program mode is selected. For example, in the program operation PG2_1 of the first time of the program loop, the voltage (Vpgm1+dV5) is applied to the selected word line WL127. The shift voltage dV5 is set based on the result of the write operation of the string unit SU4. The shift voltage dV5 may be the same as or different from the shift voltage dV4. The same applies to the string units SU6 and SU7.

### 2.2 Flow of Write Operation

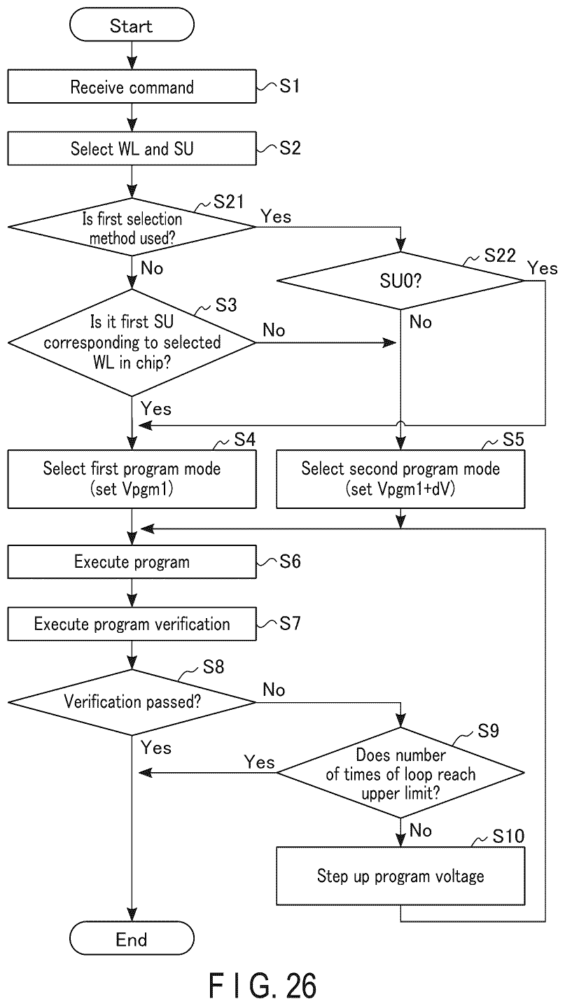

Next, an example of a flow of the write operation will be described with reference to FIG. 26. FIG. 26 is a flowchart of the write operation.

As illustrated in FIG. 26, the sequencer 53 receives a command set of the write operation from the memory controller 2 (S1).

The sequencer 53 selects the block BLK, the word line WL, the array chip 3, and the string unit SU based on the memory address ADD (S2). The sequencer 53 selects either the first selection method or the second selection method based on the selected word line WL.

In a case where the first selection method is selected (S21_Yes), the sequencer 53 checks whether the selected string unit SU is the string unit SU0 (S22). That is, the sequencer 53 checks whether the selected string unit SU is the first string unit SU of the first array chip 3 corresponding to the selected word line WL.

In a case where the selected string unit SU is the string unit SU0 (S22_Yes), the sequencer 53 selects the first program mode (S4). On the other hand, in a case where the selected string unit SU is not the string unit SU0 (S22_No), the sequencer 53 selects the first program mode (S5).

In a case where the second selection method is selected, that is, in a case where the first selection method is not selected (S21_No), the sequencer 53 checks whether the selected string unit SU is the first string unit SU corresponding to the selected word line WL in the array chip 3 (S3).

In a case where the selected string unit SU is the first string unit SU (S3_Yes), the sequencer 53 selects the first program mode (S4). On the other hand, in a case where the selected string unit SU is not the first string unit SU (S3 No), the sequencer 53 selects the second program mode (S5).

The flow after S6 is similar to that in FIG. 17.

### 2.3 Effects According to Present Embodiment

The configuration according to the present embodiment provides the same effects as those of the first embodiment.

Furthermore, with the configuration according to the present embodiment, in a case where the variation in the write characteristics by the array chip 3 is relatively small, the first program mode can be applied to the write operation of the first string unit SU of the first array chip 3, and the second program mode can be applied to the write operation of the other string units SU. As a result, the number of string units SU to which the first program mode is applied can be suppressed. Therefore, the processing capability of the write operation can be improved. That is, the processing capability of the semiconductor memory device 1 can be improved.

### 2.4 Modification

Next, a modification of the second embodiment will be described. In the present example, similarly to the first modification of the first embodiment, a case where the write operation is executed sequentially from the word line WL (memory cell transistor MC) on the source line SL side will be described. Hereinafter, differences from the second embodiment will be mainly described.

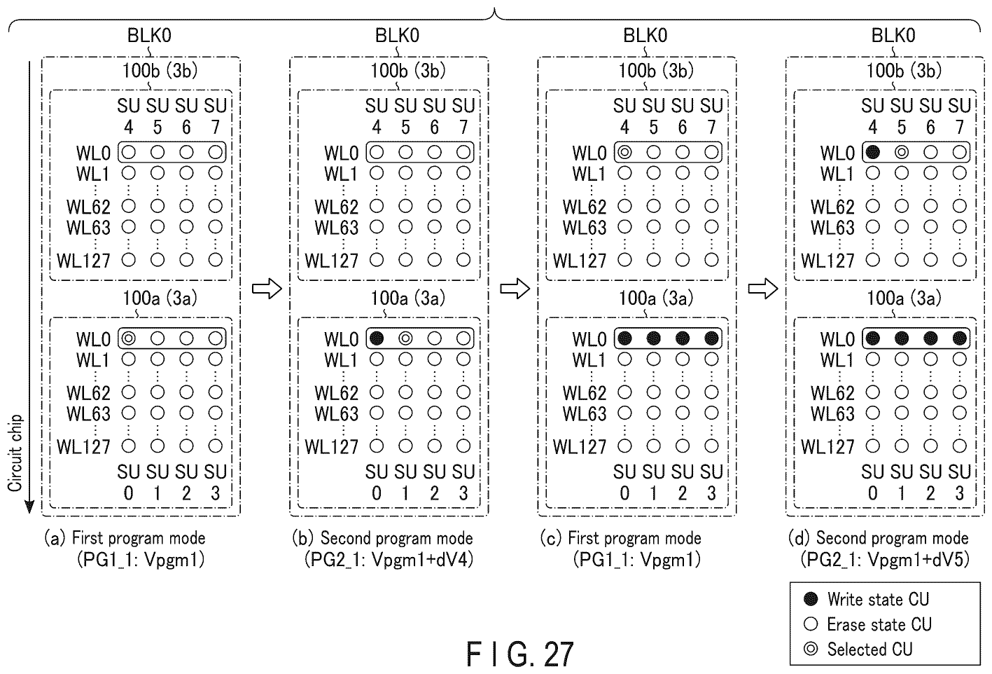

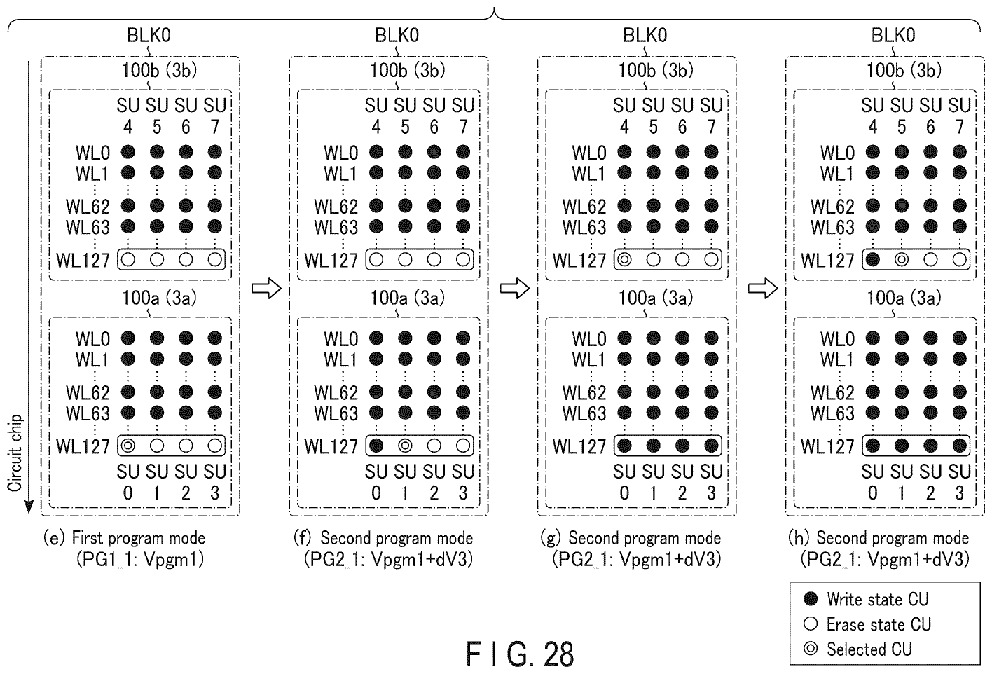

A specific example of the operation mode selection will be described with reference to FIGS. 27 and 28. FIGS. 27 and 28 are diagrams illustrating an example of the selection of the operation mode in the block BLK0. The example of FIG. 27 illustrates a case where the word line WL0 is selected. The example of FIG. 28 illustrates a case where the word line WL127 is selected.

In this example, as in the second embodiment, the method of selecting the operation mode of the write operation is different depending on the word line WL. More specifically, for example, in a case where the selected word line WL of the write operation is the word line WL arranged on the bit line BL side, the first selection method is applied. On the other hand, for example, in a case where the selected word line WL of the write operation is the word line WL arranged on the source line SL side, the second selection method is applied.

As illustrated in FIGS. 27 and 28, the configuration of the block BLK0 is similar to that in FIG. 20 of the first modification of the first embodiment. In each of the memory cell arrays 100a and 100b, 128 word lines WL0 to WL127 are provided from the source line SL side toward the bit line BL side. In other words, the word lines WL0 to WL127 of the array chips 3 are sequentially arranged in order toward the circuit chip 4.

First, a specific example of the second selection method will be described with reference to FIG. 27. In this example, the word line WL0 is disposed on the source line SL side. Therefore, in a case where the selected word line WL is the word line WL0, the second selection method is applied.

The write operation in FIGS. 27(a) to (d) is similar to the write operation in FIGS. 25(e) to (h) of the second embodiment. If the selected string unit SU is the string unit SU0 or SU4, the first program mode is selected. On the other hand, if the selected string unit SU is one of the string units SU1 to SU3 or SU5 to SU7, the second program mode is selected.

Next, a specific example of the first selection method will be described with reference to FIG. 28. In this example, the word line WL127 is disposed on the bit line BL side. Therefore, in a case where the selected word line WL is the word line WL127, the second selection method is applied.

The write operation in FIGS. 28(e) to (h) is similar to the write operation in FIGS. 24(a) to (d) of the second embodiment. If the selected string unit SU is the string unit SU0, the first program mode is selected. On the other hand, if the selected string unit SU is any of the string units SU1 to SU7, the second program mode is selected.

### 2.5 Effects According to Modifications of Second Embodiment

The configuration according to the modification of the second embodiment provides the same effects as those of the second embodiment.

### 3. Third Embodiment

Next, a third embodiment will be described. In the third embodiment, a method of setting the shift voltage dV different from the first and second embodiments will be described. Hereinafter, differences from the first and second embodiments will be mainly described.

### 3.1 Specific Example of Operation Mode Selection

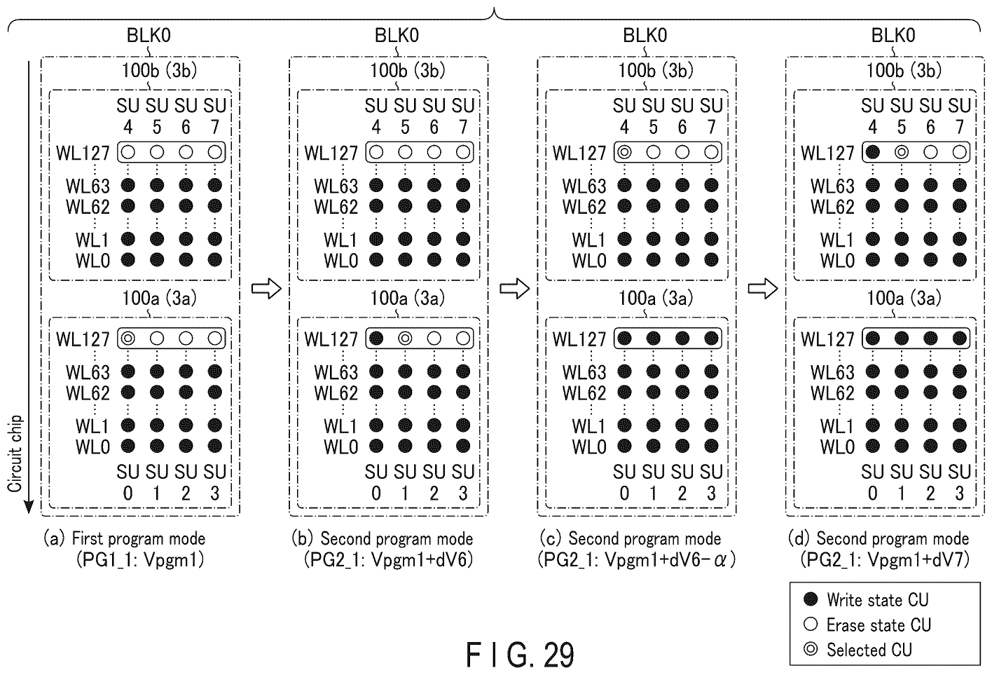

First, a specific example of operation mode selection will be described with reference to FIG. 29. FIG. 29 is a diagram illustrating an example of the selection of the operation mode in the block BLK0. The example of FIG. 29 illustrates a case where the word line WL127 is selected.

In the present embodiment, similarly to the first selection method described in the second embodiment, the first program mode is selected in a case where the selected string unit SU of the write operation is the first string unit SU of the first array chip 3 corresponding to the selected word line WL. Then, in a case where the selected string unit SU is another string unit SU, the second program mode is selected. That is, in a case where the selected string unit SU is the string unit SU0, the first program mode is selected. On the other hand, in a case where the selected string unit SU is another string unit SU, the second program mode is selected.

The shift voltage in the second program mode is different for each of the array chips 3. For example, in a case where the selected string unit SU is included in the first array chip 3, as in the first embodiment, the shift voltage dV is set based on the result of the write operation of the first string unit SU in which the first program mode is selected. That is, the voltage (Vpgm1+dV) is set as the program voltage Vpgms of the program operation PG2_1. More specifically, for example, in a case where the selected string unit SU is one of the string units SU1 to SU3 of the array chip 3a, the shift voltage dV is set. The shift voltage dV is based on the result of the write operation of the string unit SU0. In addition, in a case where the selected string unit SU is the first string unit SU of the second and subsequent selected array chips 3, the voltage (dV−α) is set as the shift voltage. A correction value a is a preset positive voltage value smaller than the voltage dV. The voltage dV and the voltage (dV−α) have a relationship of dV>(dV−α)>0. That is, the voltage (Vpgm1+dV−α) is set as the program voltage Vpgms of the program operation PG2_1. The voltage Vpgm1, the voltage (Vpgm1+dV), and the voltage (Vpgm1+dV−α) have a relationship of Vpgm1<(Vpgm1+dV−α)<(Vpgm1+dV). More specifically, for example, in a case where the selected string unit SU is the string unit SU4 of the array chip 3b, the shift voltage (dV−α) is set. In a case where the selected string unit SU is included in the second and subsequent selected array chips 3 and not the first string unit SU, a voltage dV′ is set as the shift voltage. The shift voltage dV′ is based on the result of the write operation of the first string unit SU of the second and subsequent selected array chip 3. That is, the voltage (Vpgm1+dV′) is set as the program voltage Vpgms of the program operation PG2_1. More specifically, for example, in a case where the selected string unit SU is one of the string units SU5 to SU7 of the array chip 3b, the voltage dV′ is set as the shift voltage. The shift voltage dV′ is based on the result of the write operation of the string unit SU4.

As illustrated in FIG. 29, the configuration of the block BLK0 is similar to that in FIG. 16 of the first embodiment.

FIG. 29(a) illustrates a state in which the string unit SU0 of the array chip 3a is selected. The string unit SU0 is the first string unit SU of the first array chip 3 corresponding to the selected word line WL127. Therefore, in the write operation of the string unit SU0, the first program mode is selected. For example, in the program operation PG1_1 of the first time of the program loop, the voltage Vpgm1 is applied to the selected word line WL127.

FIG. 29(b) illustrates a state in which the string unit SU1 of the array chip 3a is selected. The string unit SU1 is not the first string unit SU (that is, the string unit SU0) of the first array chip 3 corresponding to the selected word line WL127. Therefore, in the write operation of the string unit SU1, the second program mode is selected. For example, in the program operation PG2_1 of the first time of the program loop, the voltage (Vpgm1+dV6) is applied to the selected word line WL127. The shift voltage dV6 is set based on the result of the write operation of the string unit SU0. The same applies to the string units SU2 and SU3.

FIG. 29(c) illustrates a state in which the string unit SU4 of the array chip 3b is selected. The string unit SU4 is not the first string unit SU (that is, the string unit SU0) corresponding to the selected word line WL127. Therefore, in the write operation of the string unit SU4, the second program mode is selected. For example, in the program operation PG2_1 of the first time of the program loop, the voltage (Vpgm1+dV6−α) is applied to the selected word line WL127. The shift voltage (dV6−α) is lower than the shift voltage dV6.

FIG. 29(d) illustrates a state in which the string unit SU5 of the array chip 3b is selected. Similarly to the string unit SU4, the second program mode is selected in the write operation of the string unit SU5. For example, in the program operation PG2_1 of the first time of the program loop, the voltage (Vpgm1+dV7) is applied to the selected word line WL127. The shift voltage dV7 is set based on the result of the write operation of the string unit SU4. The shift voltage dV7 may be the same as or different from the shift voltage dV6. The same applies to the string units SU6 and SU7.

### 3.2 Flow of Write Operation

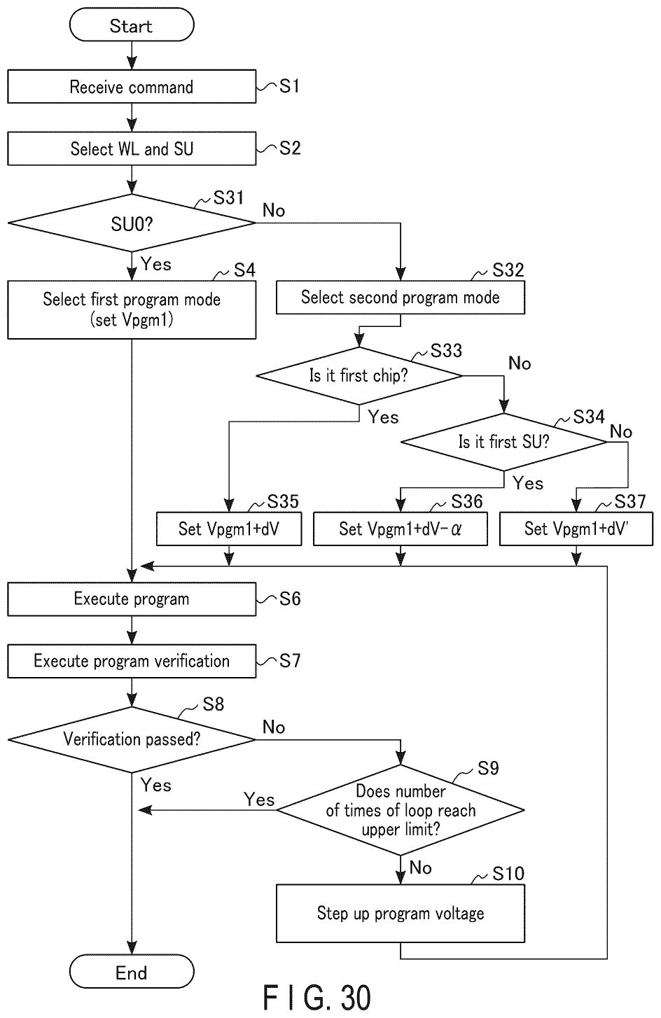

Next, an example of a flow of the write operation will be described with reference to FIG. 30. FIG. 30 is a flowchart of the write operation.

As illustrated in FIG. 30, the sequencer 53 receives a command set of the write operation from the memory controller 2 (S1).

The sequencer 53 selects the block BLK, the word line WL, the array chip 3, and the string unit SU based on the memory address ADD (S2).

The sequencer 53 checks whether the selected string unit SU is the string unit SU0 (S31). That is, the sequencer 53 checks whether the selected string unit SU is the first string unit SU of the first array chip 3 corresponding to the selected word line WL.

In a case where the selected string unit SU is the string unit SU0 (S31_Yes), the sequencer 53 selects the first program mode (S4). Then, the sequencer 53 sets the voltage Vpgm1 as the program voltage Vpgmf in the program operation PG1_1 of the first time of the program loop.

In a case where the selected string unit SU is not the string unit SU0 (S31_No), the sequencer 53 selects the second program mode (S32).

After selecting the second program mode, the sequencer 53 confirms whether the selected array chip 3 is the first array chip 3 (that is, the array chip 3a) (S33).

In the case of the first array chip 3 (S33_Yes), the sequencer 53 sets the voltage (Vpgm1+dV) as the program voltage Vpgms in the program operation PG2_1 of the first time of the program loop (S35). In the example of FIG. 29, the voltage (Vpgm1+dV6) is set.

If it is not the first array chip 3 (S33_No), the sequencer 53 checks whether the selected string unit SU is the first string unit SU in the array chip 3 (S34). For example, the sequencer 53 checks whether the selected string unit SU is the string unit SU4.

In the case of the first string unit SU (S34_Yes), the sequencer 53 sets the voltage (Vpgm1+dV−α) as the program voltage Vpgms in the program operation PG2_1 of the first time of the program loop (S36). In the example of FIG. 29, the voltage (Vpgm1+dV6−α) is set.

In a case where it is not the first string unit SU (S34_No), the sequencer 53 sets the voltage (Vpgm1+dV′) as the program voltage Vpgms in the program operation PG2_1 of the first time of the program loop (S37). In the example of FIG. 29, the voltage (Vpgm1+dV7) is set.

The flow after S6 is similar to that in FIG. 17.

### 3.3 Effects According to Present Embodiment

The configuration according to the present embodiment provides the same effects as those of the first embodiment.

Furthermore, with the configuration according to the present embodiment, the second program mode can be selected for the write operation of the first string unit SU of the array chip 3 selected second or later. Then, in the second and subsequent array chips 3, a shift voltage different from that of the first array chip 3 can be set. For example, the shift voltage (dV−α) of the write operation of the first string unit SU of the second array chip 3 can be set to be lower than the shift voltage dV of the write operation of the first array chip 3. As a result, even in a case where the variation in the write characteristics in the array chip 3 is relatively large, the occurrence of over-programming can be suppressed. Therefore, the reliability of the semiconductor memory device 1 can be improved.

Furthermore, by selecting the second program mode in the write operation of the first string unit SU of the array chip 3 selected second or later, the number of the string units SU to which the first program mode is applied can be suppressed. Therefore, the processing capability of the write operation can be improved. That is, the processing capability of the semiconductor memory device 1 can be improved.

The present embodiment can be combined with the first modification and the second modification of the first embodiment. In addition, the present embodiment can be combined with the second embodiment and the modifications of the second embodiment.

### 4. Others

The semiconductor memory device according to the above embodiments includes a first chip (3a), a second chip (3b), and a third chip (4). The first chip includes a first pillar (MP) including a first memory cell (MC0) and a second pillar (MP) including a second memory cell (MC0). The second chip includes a third pillar (MP) including a third memory cell (MC0) and a fourth pillar (MP) including a fourth memory cell (MC0). The third chip includes a row decoder (20) to which a first word line (WL0) coupled to a gate of each of the first to the fourth memory cells is coupled and a controller (53) configured to execute a write operation in which a program loop is repeated. The program loop includes a program operation and a program verify operation. In a first time of the program operation of the write operation of the first memory cell, the row decoder applies a first program voltage (Vpgm1) to the first word line. In a first time of the program operation of the write operation of the second memory cell, the row decoder applies a second program voltage (Vpgm1+dV1) higher than the first program voltage to the first word line. In a first time of the program operation of the write operation of the third memory cell, the row decoder applies a third program voltage (Vpgm1) to the first word line. In a first time of the program operation of the write operation of the fourth memory cell, the row decoder applies a fourth program voltage (Vpgm1+dV2) higher than the third program voltage to the first word line.

By applying the above embodiments, it is possible to provide a semiconductor memory device capable of improving processing capability.

Note that the embodiment is not limited to the above-described embodiments, and various modifications are possible.

The “coupling” in the above embodiment also includes a state of being coupled indirectly, for example, with a transistor or a resistor interposed therebetween.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a first chip including:
a first pillar including a first memory cell; and
a second pillar including a second memory cell;
a second chip including:
a third pillar including a third memory cell; and
a fourth pillar including a fourth memory cell; and
a third chip including:
a row decoder to which a first word line coupled to a gate of each of the first to the fourth memory cells is coupled; and
a controller configured to execute a write operation in which a program loop is repeated, the program loop including a program operation and a program verify operation, wherein
in a first time of the program operation of the write operation of the first memory cell, the row decoder applies a first program voltage to the first word line,
in a first time of the program operation of the write operation of the second memory cell, the row decoder applies a second program voltage higher than the first program voltage to the first word line,
in a first time of the program operation of the write operation of the third memory cell, the row decoder applies a third program voltage to the first word line, and
in a first time of the program operation of the write operation of the fourth memory cell, the row decoder applies a fourth program voltage higher than the third program voltage to the first word line.

2. The semiconductor memory device according to claim 1, wherein
the controller sets the second program voltage based on a result of the write operation of the first memory cell, and sets the fourth program voltage based on a result of the write operation of the third memory cell.

3. The semiconductor memory device according to claim 1, wherein
the first program voltage and the third program voltage are identical.

4. The semiconductor memory device according to claim 1, wherein
a number of times of the program loop in the write operation of the second memory cell is smaller than a number of times of the program loop in the write operation of the first memory cell.

5. The semiconductor memory device according to claim 1, wherein
the first program voltage increases along with repetition of the program loop.

6. The semiconductor memory device according to claim 1, wherein
the third chip further includes a sense amplifier to which a bit line commonly coupled to one end of each of the first to the fourth pillars is coupled.

7. The semiconductor memory device according to claim 1, wherein
the first pillar further includes a first selection transistor coupled in series with the first memory cell and having a gate coupled to the row decoder via a first select gate line,
the second pillar further includes a second selection transistor coupled in series with the second memory cell and having a gate coupled to the row decoder via a second select gate line,
the third pillar further includes a third selection transistor coupled in series with the third memory cell and having a gate coupled to the row decoder via a third select gate line, and
the fourth pillar further includes a fourth selection transistor coupled in series with the fourth memory cell and having a gate coupled to the row decoder via a fourth select gate line.

8. The semiconductor memory device according to claim 1, wherein
the first pillar and the third pillar extend in a first direction and are arranged side by side in the first direction.

9. The semiconductor memory device according to claim 1, wherein
the first pillar includes a semiconductor layer and a charge storage layer.

10. The semiconductor memory device according to claim 1, wherein
the second chip is bonded to a first surface of the first chip, and the third chip is bonded to a second surface of the first chip facing the first surface.

11. The semiconductor memory device according to claim 1, wherein
the first pillar further includes a fifth memory cell coupled in series with the first memory cell,
the second pillar further includes a sixth memory cell coupled in series with the second memory cell,
the third pillar further includes a seventh memory cell coupled in series with the third memory cell,
the fourth pillar further includes an eighth memory cell coupled in series with the fourth memory cell,
a gate of each of the fifth to the eighth memory cells is coupled to the row decoder via a second word line,
in a first time of the program operation of the write operation of the fifth memory cell, the row decoder applies a fifth program voltage to the second word line,
in a first time of the program operation of the write operation of the sixth memory cell, the row decoder applies a sixth program voltage higher than the fifth program voltage to the second word line,
in a first time of the program operation of the write operation of the seventh memory cell, the row decoder applies the sixth program voltage to the second word line, and
in a first time of the program operation of the write operation of the eighth memory cell, the row decoder applies the sixth program voltage to the second word line.

12. The semiconductor memory device according to claim 11, wherein
the controller sets the sixth program voltage based on a result of the write operation of the fifth memory cell.

13. The semiconductor memory device according to claim 11, wherein
the first program voltage, the third program voltage, and the fifth program voltage are identical.

14. The semiconductor memory device according to claim 1, wherein
the controller sets:
the second program voltage based on a result of the write operation of the first memory cell;
the third program voltage based on the second program voltage; and
the fourth program voltage based on a result of the write operation of the third memory cell.

15. The semiconductor memory device according to claim 1, wherein
the third program voltage is higher than the first program voltage and lower than the second program voltage.
